(19) United States
(12) Patent Application Publication
(10) Pub. No.: US 2024/0280631 A1
(43) Pub. Date: Aug. 22, 2024

(54) IC NOISE IMMUNITY DETECTION DEVICE AND IC NOISE IMMUNITY DETECTION METHOD

(71) Applicant: Mitsubishi Electric Corporation, Tokyo (JP)

(72) Inventors: Yusuke YAMAKAJI, Chiyoda-ku, Tokyo (JP); Masaomi WASHINO, Chiyoda-ku, Tokyo (JP); Nobuyuki HARUNA, Chiyoda-ku, Tokyo (JP)

(73) Assignee: Mitsubishi Electric Corporation, Tokyo (JP)

(21) Appl. No.: 18/290,459

(22) PCT Filed: May 21, 2021
(86) PCT No.: PCT/JP2021/019384

§ 371 Date: Nov. 14, 2023

(51) Int. Cl. G01R 31/28; G01R 1/067

(52) U.S. Cl. CPC G01R 31/2879; G01R 1/06733; G01R 31/2874

(57) ABSTRACT

A signal generation unit outputs a first AC signal and a second AC signal having different phases as noise. A first coaxial cable transmits a first AC signal. A second coaxial cable transmits a second AC signal. A first probe is connected to the first coaxial cable and arranged in proximity to an IC on a printed circuit board to apply the first AC signal to the IC. A second probe is connected to the second coaxial cable and arranged in proximity to the IC to apply the second AC signal to the IC. A determination device determines whether the IC is malfunctioning, based on a state of the IC after application of the first AC signal and the second AC signal.

### TECHNICAL FIELD

The present disclosure relates to an IC noise immunity detection device, an IC noise immunity detection method, and an IC internal impedance measurement method.

### BACKGROUND ART

It is known that electromagnetic noise propagating from the outside of an integrated circuit (IC) causes malfunction (momentary interruption or abnormal operation) or destruction of the IC. Testing that replicates electromagnetic noise is performed to determine the presence/absence of malfunction or destruction before shipment of equipment containing ICs. Testing that replicates electromagnetic noise includes electrical fast transient/burst (EFT/B) testing, electro static discharge (ESD) testing, conduction immunity testing, radiation immunity testing, and lightning surge testing. When the result of testing does not satisfy the specifications, redesigning is performed. Methods of evaluating IC resistance against electromagnetic noise which is a cause of malfunction include the direct power injection (DPI) method defined by IEC62132-4 in IEC (International Electrotechnical commission) 621132, and the surface scan method defined by IEC62132-9.

An IC noise immunity detection device that detects noise immunity of an IC through the following four steps is known (for example, see PTL 1).

In a first step, the IC noise immunity detection device allows a noise source to inject common mode noise into a transmission line in an electronic product while sweeping a frequency.

In a second step, the IC noise immunity detection device measures the frequency characteristics indicating a noise level in each frequency of the common mode noise injected into a terminal of a device in the electronic product through the transmission line.

In a third step, the IC noise immunity detection device acquires the immunity characteristics indicating the noise level in each noise frequency at which a malfunction occurs in the device.

In a fourth step, the IC noise immunity detection device specifies a frequency band of common mode noise that causes a malfunction in the electronic product, based on the frequency characteristics and the immunity characteristics.

A method of determining a malfunction by applying noise to an IC under test in a non-contact manner so as to reduce effects on a measurement system is also known (for example, see NPL 1).

### CITATION LIST

### Patent Literature

PTL 1: Japanese Patent Laying-Open No. 2020-30073 (page 6, lines 15 to 22, FIG. 1)

### Non Patent Literature

NPL 1: Investigation of Semi-Rigid Coaxial Test Probes as RF Injection Devices for Immunity Tests at PCB Level, IEEE open Access, VOLUME8, 2020

### SUMMARY OF INVENTION

### Technical Problem

In order to measure a malfunction condition of an IC, it is necessary to apply a signal to a terminal of an IC under test from the outside and determine a propagation path of the applied signal.

In conventional approaches using non-contact probes, an electric field or magnetic field can be applied. However, a return path of current is produced according to the Kirchhoff's Law due to a current source or voltage source generated by the applied electric field or magnetic field. The return path is produced by a parasitic component such as electric field coupling and magnetic field coupling dependent on spatial distance and structure, and the like. The propagation path therefore cannot be determined only by arranging a non-contact probe.

The propagation path can be determined by bringing a contact probe into contact with an IC under test and providing a return path. However, bringing a probe into contact changes the operating conditions of the IC under test, making it difficult to accurately measure a condition of malfunction (hereinafter referred to as malfunction condition) in the actual operative state of the IC.

An object of the present disclosure is therefore to provide an IC noise immunity detection device capable of accurately measuring an IC malfunction condition, an IC noise immunity detection method, and an IC internal impedance measurement method.

### Solution to Problem

An IC noise immunity detection device according to the present disclosure includes: a signal generation unit to output a first AC signal and a second AC signal with different phases as noise; a first coaxial cable to transmit the first AC signal; a second coaxial cable to transmit the second AC signal; a first probe connected to an end opposite to the signal generation unit in the first coaxial cable and arranged in proximity to an IC on a printed circuit board; a second probe connected to an end opposite to the signal generation unit in the second coaxial cable and arranged in proximity to the IC; and a determination device to determine whether the IC is malfunctioning, based on an operating state of the IC or a device having the IC after the first AC signal and the second AC signal are applied.

An IC noise immunity detection device according to the present disclosure includes: a signal generation unit to output a first AC signal and a second AC signal with different phases; a plurality of first coaxial cables, each transmitting the first AC signal; a plurality of second coaxial cables, each transmitting the second AC signal; a plurality of first probes each connected to a corresponding first coaxial cable and arranged in proximity to an IC on a printed circuit board to apply the first AC signal to the IC; a plurality of second probes each connected to a corresponding second coaxial cable and arranged in proximity to the IC to apply the second AC signal to the IC; a plurality of third probes each arranged in proximity to the IC to measure an output signal of the IC; a plurality of third coaxial cables each connected to a corresponding third probe to transmit an output signal of the IC; a determination device to determine whether the IC is malfunctioning, based on an output signal of the IC input from the third probe, after application of the first AC signal and the second AC signal; a first switch provided between the first coaxial cables and the signal generation unit to switch one of the first coaxial cables to be connected to the signal generation unit; a second switch provided between the second coaxial cables and the signal generation unit to switch one of the second coaxial cables to be connected to the signal generation unit; and a third switch provided between the third coaxial cables and the determination device to switch one of the third coaxial cables to be connected to the determination device.

An IC noise immunity detection method according to the present disclosure is a noise immunity detection method in an IC noise immunity detection device comprising a signal generation unit to output a first AC signal and a second AC signal with different phases, a first coaxial cable to transmit the first AC signal, a second coaxial cable to transmit the second AC signal, a first probe connected to the first coaxial cable, a second probe connected to the second coaxial cable, and a determination device. The IC noise immunity detection method according to the present disclosure includes the steps of: arranging the first probe and the second probe in proximity to the IC; outputting, by the signal generation unit, the first AC signal and the second AC signal; and determining, by the determination device, whether the IC is malfunctioning, based on a state of the IC, or a printed circuit board having the IC, or a different printed circuit board connected to the printed circuit board having the IC.

An IC internal impedance measurement method according to the present disclosure includes the steps of: measuring an electric field generated by an output terminal having an output signal not changing in an IC in an operative state, using an electric field probe; measuring a magnetic field generated by the output terminal, using a magnetic field probe; and calculating an internal impedance of an output terminal of the IC, based on the measured electric field and the measured magnetic field.

An IC internal impedance measurement method according to the present disclosure includes the steps of: measuring a voltage applied to an input terminal under test of an IC in an operative state; injecting a signal or a modulated signal of a known pseudo random number having an amplitude smaller than an amplitude of the voltage into the input terminal; measuring an electric field generated by the input terminal, using an electric field probe; measuring a magnetic field generated by the input terminal, using a magnetic field probe; and calculating an internal impedance of the input terminal, based on the measured electric field and the measured magnetic field.

An IC internal impedance measurement method according to the present disclosure includes the steps of: measuring an electric field generated by an input terminal with a known impedance, using an electric field probe; measuring a magnetic field generated by the input terminal with a known impedance, using a magnetic field probe; calculating a frequency characteristic of a complex correction coefficient, using the known impedance, and the electric field and the magnetic field generated by the input terminal with a known impedance; measuring an electric field generated by an input terminal under test, using an electric field probe; measuring a magnetic field generated by the input terminal under test, using a magnetic field probe; and calculating an internal impedance of the input terminal under test, using the frequency characteristic of the complex correction coefficient, and the electric field and the magnetic field generated by the input terminal under test.

### Advantageous Effects of Invention

According to the present disclosure, an IC malfunction condition can be accurately measured.

### BRIEF DESCRIPTION OF DRAWINGS

FIG. 1 is a diagram illustrating a configuration of an IC noise immunity detection device in a first embodiment.

FIG. 2 is a diagram for explaining injection of a first AC signal and a second AC signal into an IC 51.

FIG. 3 is a diagram illustrating a configuration example of a determination device 70.

FIG. 4 is a diagram illustrating an example of a coaxial probe.

FIG. 5 is a flowchart illustrating the procedure of an IC noise immunity detection method in the first embodiment.

FIG. 6 is a schematic diagram of a first measurement method in the first embodiment.

FIG. 7 is a schematic diagram of a second measurement method in the first embodiment.

FIG. 8 is a schematic diagram of a third measurement method in the first embodiment.

FIG. 9 is a schematic diagram of a conventional measurement device.

FIG. 10 is a schematic diagram of another conventional measurement device.

FIG. 11 is a flowchart illustrating the procedure of an IC noise immunity detection method in a second embodiment.

FIG. 12 is a diagram illustrating an example of a response map in the second embodiment.

FIG. 13 is a flowchart illustrating the procedure of a method of determining a malfunction condition using two response maps.

FIG. 14 is a diagram illustrating a response map for a second IC.

FIG. 15 is a diagram for explaining a method of specifying a malfunction condition using two response maps.

FIG. 16 is a flowchart illustrating the procedure of an IC noise immunity detection method in a modification of the second embodiment.

FIG. 17 is a diagram illustrating an example of a response map in a modification of the second embodiment.

FIG. 18 is a flowchart illustrating the procedure of a method of measuring an internal impedance of an output terminal of an IC in a third embodiment.

FIG. 19 is a diagram illustrating an example of a response map including a description of internal impedance.

FIG. 20 is a flowchart illustrating the procedure of a method of measuring an internal impedance of an input terminal of an IC in a fourth embodiment.

FIG. 21 is a diagram illustrating a configuration of an IC noise immunity detection device in a fifth embodiment.

FIG. 22 is a diagram illustrating a configuration of an IC noise immunity detection device in a modification of the fifth embodiment.

FIG. 23 is a diagram illustrating a configuration of an IC noise immunity detection device according to a sixth embodiment.

FIG. 24 is a diagram illustrating a configuration of an IC noise immunity detection device in a first modification of the sixth embodiment.

FIG. 25 is a diagram illustrating a configuration of an IC noise immunity detection device in a second modification of the sixth embodiment.

FIG. 26 is a diagram illustrating a configuration of an IC noise immunity detection device in a third modification of the sixth embodiment.

FIG. 27 is a diagram illustrating a part of an IC noise immunity detection device in a seventh embodiment.

FIG. 28 is a diagram illustrating a measurement result obtained when noise is applied to a printed circuit board 50.

FIG. 29 is a diagram illustrating a measurement result obtained when a non-contact coaxial probe (electric field probe) is used and a measurement result obtained when a magnetic field probe is used.

FIG. 30 is a diagram illustrating a measurement result of a normal output (1.35 V) and an abnormal output of IC 51 obtained when noise is applied to power supply IC 51.

FIG. 31 is a diagram showing the result obtained when a signal of 10 V is injected into a feedback terminal of a power supply IC.

FIG. 32 is a diagram illustrating a first probe 40 in a first modification of the seventh embodiment.

FIG. 33 is a diagram illustrating a partial configuration of an IC noise immunity detection device in an eighth embodiment.

FIG. 34 is a diagram showing the malfunction condition measurement result obtained when noise is applied to differential wiring.

FIG. 35 is a diagram illustrating a partial configuration of an IC noise immunity detection device in a ninth embodiment.

FIG. 36 is a diagram illustrating a configuration of an IC noise immunity detection device in a tenth embodiment.

FIG. 37 is a diagram illustrating a configuration of an IC noise immunity detection device in an eleventh embodiment.

FIG. 38 is a diagram illustrating an electromagnetic field probe in a twelfth embodiment.

FIG. 39 is a diagram illustrating an electromagnetic field probe in a modification of the twelfth embodiment.

FIG. 40 is a diagram illustrating an estimation result of internal impedance Z(f) in a fourteenth embodiment.

FIG. 41 is a diagram showing the frequency characteristics of an estimation value of internal impedance Z(f) for a 50Ω terminator when calibration by a correction complex coefficient β(f) according to the fourteenth embodiment is performed and when calibration is not performed.

FIG. 42 is a flowchart illustrating the procedure of a method of measuring an internal impedance in the fourteenth embodiment.

### DESCRIPTION OF EMBODIMENTS

Embodiments will be described below with reference to the drawings.

### First Embodiment

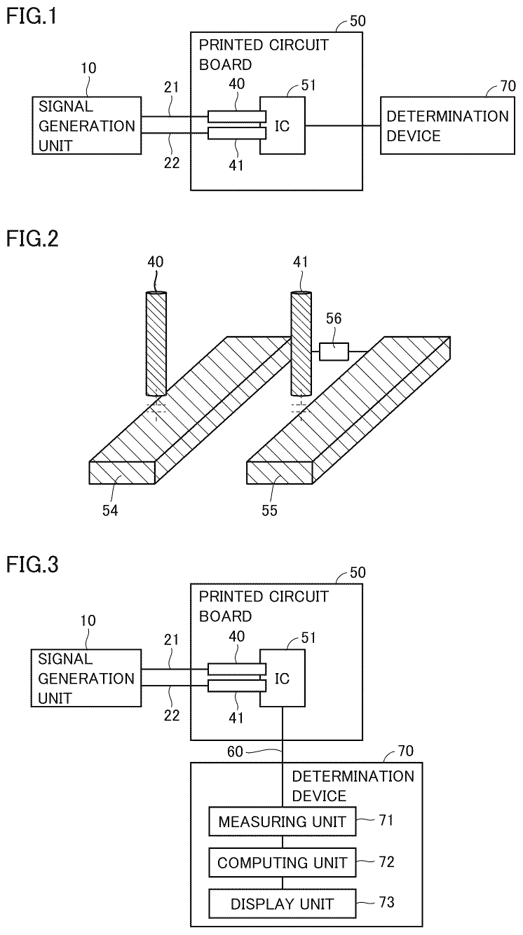

FIG. 1 is a diagram illustrating a configuration of an IC noise immunity detection device in a first embodiment. This IC noise immunity detection device detects the noise immunity of an IC 51 on a printed circuit board 50. Noise is typically a signal produced in the inside or outside of equipment under test and propagating through wiring or space, and in the present embodiment, a signal intentionally applied from the outside is referred to as noise unless otherwise specified. When a signal source is embedded in a printed circuit board at the time of board design, this signal source may be considered as a noise generation source.

The noise immunity detection device includes a signal generation unit 10, a first probe 40, a second probe 41, a determination device 70, a first coaxial cable 21, and a second coaxial cable 22.

Signal generation unit 10 outputs a first AC signal and a second AC signal having different phases as noise. For example, signal generation unit 10 may output a first AC signal and a second AC signal with 10 or more periods per bandwidth.

First coaxial cable 21 transmits a first AC signal. Second coaxial cable 22 transmits a second AC signal. The phase difference between the first AC signal and the second AC signal can be 180 degrees. In other words, the first AC signal and the second AC signal can be differential signals. Alternatively, the phase difference between the first AC signal and the second AC signal may be 120 degrees.

First probe 40 is connected to first coaxial cable 21. First probe 40 is arranged in proximity to IC 51 on printed circuit board 50 and injects the first AC signal into IC 51. First probe 40 may be arranged at IC 51 on printed circuit board 50 in a non-contact manner.

Second probe 41 is connected to second coaxial cable 22. Second probe 41 is arranged in proximity to the IC on printed circuit board 50 and injects the second AC signal into IC 51. Second probe 41 may be arranged at IC 51 on printed circuit board 50 in a non-contact manner.

Determination device 70 determines whether IC 51 is malfunctioning, based on a state of IC 51 after injection of the first AC signal and the second AC signal. For example, determination device 70 may determine whether IC 51 is malfunctioning, based on an output signal from IC 501.

A terminal into which the first AC signal and the second AC signal is injected may be a signal input terminal or a signal input/output terminal of IC 51, and a terminal at which an output signal from IC 51 is observed may be a signal output terminal or a signal input/output terminal of IC 51.

### (Signal Generation Unit 10)

Signal generation unit 10 generates two signals for evaluation. Two signals are a first AC signal and a second AC signal having different phases. The first AC signal generated by signal generation unit 10 is injected into first probe 40 through first coaxial cable 21. The second AC signal generated by signal generation unit 10 is injected into second probe 41 through second coaxial cable 22.

For example, signal generation unit 10 is configured with a signal generator or function generator with two outputs, or two signal generators or function generators. When signal generation unit 10 is configured with two generators, the generators may be externally controlled so that they are synchronized to output a first AC signal and a second AC signal with different phases.

Signals of two or more outputs may be generated from a single generator through a coupler, a distributor, a phase shifter, or the like. Differential signals which are an example of signals having different phases may be generated using a 180-degree hybrid coupler (also called balun) or the like. The first AC signal and the second AC signal may also be generated by differentiating the electrical length of first coaxial cable 21 and the electrical length of second coaxial cable 22. However, when the electrical length is used for adjustment, the phase difference between the first AC signal and the second AC signal varies with the frequency of a signal output from signal generation unit 10. Therefore, it is preferable to make a phase difference between the first AC signal and the second AC signal by equalizing the electrical length of first coaxial cable 21 and the electrical length of second coaxial cable 22 and differentiating the two outputs of signal generation unit 10.

The amplitudes of two signals for evaluation may be different or the phases and amplitudes may be different, rather than the phases of two signals for evaluation being different as described above.

For coaxial cables 21, 22 and probes 40, 41, when dielectrics of the same material are typically used, those having the same length may be used. To be more exact, the electrical length can be accurately measured by measuring reflection characteristics or transmission characteristics using a vector network analyzer (VNA), or measuring the propagation delay time or reflection using time domain reflectometry (TDR). In particular, when a signal including a frequency signal of 1 GHz or more is output from signal generation unit 10, it is preferable to carry out measurement according to the present embodiment after measuring the electrical length considering individual differences of coaxial cables 21, 22. If the phase or amplitude varies as a result of measurement of the electrical length, the output of signal generation unit 10 is adjusted by a phase shifter, an attenuator, or the like.

### (Probe)

A signal output by signal generation unit 10 is input to first ends of coaxial cables 21 and 22. First probe 40 and second probe 41 are connected to second ends of coaxial cables 21 and 22, respectively. First probe 40 and second probe 41 may be probes of the same kind or probes of different kinds. When probes of different kinds are used, the electrical lengths differ, and the frequency characteristics of the amount of coupling with a target under test differ. Thus, it is preferable to use probes of the same kind unless there is a reason.

Probes include an electric field probe and a magnetic field probe.

An electric field probe has a coaxial core and a conductor attached to a tip end of the coaxial core. This conductor functions as an antenna. For example, an electric field probe with a patch structure or a coaxial probe is used as an electric field probe. The tip end of the coaxial core of the electric field probe is formed as an open end to produce a potential difference between the tip end of the coaxial core and a terminal or wiring of an IC under test so that an electric field is superimposed on the target under test. Electric power is thus injected into the target under test.

A magnetic field probe has a coaxial core and a coaxial outer conductor connected to a tip end of the coaxial core. Alternatively, the magnetic field probe has a coaxial core, a coaxial outer conductor, and a resistance member of 50Ω between the tip end of the coaxial core and the coaxial outer conductor. The tip end of the coaxial core is short-circuited with the coaxial outer conductor or short-circuited via an impedance element to allow current to flow through the tip end of the coaxial core to apply a magnetic field to a target under test. Electric power is thus injected into the target under test. The magnetic field probe does not necessarily have the coaxial core and may have a coated wire wound into a loop. A voltage is applied between both ends of the coated wire. In the case of a magnetic field probe, a coupling capacitor (a capacitor provided in series with the core, also called DC-cut capacitor) may be provided on a core of a coaxial cable. For example, when a bipolar power supply described later is used as an amplifier, a short-circuit protective circuit of the bipolar power supply acts to prevent superimposition of a high-frequency component. In such a case, the provision of a coupling capacitor between the magnetic field probe and the bipolar power supply prevents the short-circuit preventive circuit from acting and enables superimposition of a necessary high-frequency signal on the magnetic field probe. In a device that generates a pulsed signal such as a short pulse generator, overcurrent may also flow through the magnetic field probe or the signal generator, in a low-frequency component with a large amplitude component (typically, 1.8 kHz or less which is a harmonic 30 times higher than 60 Hz; in the present embodiment, a frequency band of 100 kHz or lower), and the coupling capacitor can prevent such overcurrent. The low frequency band may be removed using a filter other than a coupling capacitor, such as a high-pass filter, a band-pass filter, or a band-reject filer.

Electric field probes or magnetic field probes include those with intentionally increased directivity and those intentionally brought closer to omni-directivity.

For those with known wiring orientation, such as an IC terminal, the output power of signal generation unit 10 can be reduced by increasing the amount of coupling using a directional probe. Using a directional probe can not only reduce the output power of signal generation unit 10 but also reduce a voltage applied to the probe. When a directional magnetic field probe is used, current to be fed can be reduced, leading to thin wiring and a smaller magnetic field probe. As a result, the resolution of application position can be enhanced. Thus, it is preferable to use a directional probe.

When noise is applied to an IC itself, it is preferable to use an omni-directional probe because the orientation of wiring and a bonding wire inside the IC is unknown. However, when the direction in which the amount of coupling increases can be found by rotating a directional probe relative to the IC, or when the orientation of wiring and a bonding wire inside the IC is known beforehand, it is preferable to use a directional probe.

First probe 40 and second probe 41 that are electric field probes or magnetic field probes are arranged in proximity to IC 51 on printed circuit board 50. Depending on the necessary positional resolution of the probe determined by the distance between terminals of IC 51 and the insulation breakdown distance with an applied voltage, typically, it is preferable that first probe 40 and second probe 41 are brought into proximity within 10 mm from the terminal of IC 51 under test.

Furthermore, when a tip end portion of one of first probe 40 and second probe 41 is insulated, it is preferable to arrange the tip end of the one probe in contact with the terminal of IC 51. Doing so facilitates injection of an electromagnetic field component emitted from one probe into IC 51 under test and increases the injection efficiency. As a result, since it is not necessary to output a voltage with a large amplitude from signal generation unit 10, signal generation unit 10 can be downsized, and the withstand voltage and current rating of wiring and one probe connected to signal generation unit 10 can be reduced.

When IC 51 is a lead frame type, it is preferable to arrange one of first probe 40 and second probe 41 in proximity to a terminal of IC 51 or wiring connected to a terminal of IC 51.

One of first probe 40 and second probe 41 can be arranged on the top of IC 51, and a signal (noise) can be externally applied to a bonding wire inside IC 51. When IC 51 has a terminal protruding to the bottom, as in a flip chip-type IC and a tape automated bonding (TAB)-type IC with no wire bonding, one of first probe 40 and second probe 41 is arranged in proximity to wiring connected to a terminal of IC 51 or in proximity to the top of IC 51. By doing so, noise can be applied to a semiconductor inside IC 51, so that the noise immunity of IC 51 itself, that is, the inside of IC 51 can be measured. If a die inside IC 51 and wiring of a package can be grasped, noise can be applied to them.

One of first probe 40 and second probe 41 has been described above, and the arrangement of the other probe will now be described. The other probe is also arranged in proximity to IC 51 under test. It is preferable to arrange first probe 40 and second probe 41 for one IC 51 under test. The description will be given using some examples.

As a first example, when noise is intended to be applied to a power supply input terminal of a switched power supply, one probe is arranged in the vicinity of (for example a position at a height of 1 mm) a power supply input terminal of IC 51 under test, and the other probe is arranged in the vicinity of a GND terminal that is a current path of IC 51 under test. The arrangement of one probe in the vicinity of the GND terminal of IC 51 under test can also be applied to a single-end high-speed signal line or a sensor signal.

As a second example, when the block diagram of the inside of a semiconductor is known from a specification sheet or the like, the noise resistance performance between terminals of IC 51 can be determined by arranging two probes between wirings provided with a comparator, an operational amplifier, or a diode.

As a third example, when differential signals are used as an example of signals with different phases, noise resistance performance can be determined by a similar method. In other words, one probe is arranged in proximity to one line of a differential signal and the other probe is arranged in proximity to a differential line paired therewith. By doing so, signals with different phases or differential signals with equal amplitudes and a phase difference of 180 degrees can be injected into differential lines, and thus differential signals can be injected externally in a non-contact manner into differential lines. Thus, two probes can apply a voltage between proximate wirings or feed current between the wirings, thereby uniquely determining a propagation path of an input signal. This is because a path for a signal applied from one probe to exit to the other probe is generated. In this case, it is preferable that two probes are more proximate to the input terminal or input/output terminal of IC 51 than to the output terminal of IC 51. This is because the input terminal of IC 51 needs to receive a signal and therefore is designed with high sensitivity and susceptible to noise.

As a fourth example, when three-phase alternating current is handled, the phase difference between wirings is 120 degrees. In such a case, the malfunction resistance against noise can be measured by applying signals with a phase difference of 120 degrees to first probe 40 and second probe 41. In the method using only one probe as in a conventional example, since intended noise is unable to be applied between terminals, measurement is difficult for wiring that transmits signals with different phases.

FIG. 2 is a diagram for explaining injection of a first AC signal and a second AC signal into IC 51.

FIG. 2 shows a first AC signal and a second AC signal being injected into a first noise applied section 54 and a second noise applied section 55 using two probes 40 and 41. As shown in FIG. 2, a noise propagation path is formed through an internal impedance 56 of IC 51 connected to first noise applied section 54 and second noise applied section 55. Although not illustrated in FIG. 2, when another IC is connected to IC 51 under test, the internal impedance of another IC also serves as a current path, and thus a current path through the internal impedance of each IC is formed. In such a target under test, first probe 40 and first noise applied section 54 are connected via air by parasitic capacitance and mutual inductance. Second probe 41 and second noise applied section 55 are connected via air by parasitic capacitance and mutual inductance. When electric field probes are used as first probe 40 and second probe 41, a parasitic capacitance component is dominant, and when magnetic field probes are used, a mutual inductance component is dominant.

Since signals with different phases are injected between first probe 40 and second probe 41, a signal flows from one probe to the other probe via internal impedance 56 of IC 51. As indicated by the prior art (NPL 1), when one probe is used for measurement, a current path is not determined, and a propagation path of an applied signal is formed via a parasitic capacitance from the probe to each terminal and via the power supply of a measurement system, so that the operation tends to vary with measurement environments such as measurement conditions, equipment connected to a system power supply, and surrounding electronic equipment. As a result, it is difficult to ensure repeatability of measurement.

According to the present embodiment, since a current path can be fixed, the repeatability of measurement can be improved. Further, a return path of current is formed by forming a signal propagation path, thereby facilitating injection of a signal into a circuit.

In measurement in which a signal is externally applied, it is preferable to perform measurement with IC 51 in operation. This is because IC 51, which is a semiconductor, has internal impedance different between in operation and in non-operation. Internal impedance 56 of IC 51 in FIG. 2 changes between when IC 51 is on and when it is off.

It is preferable to provide a measurement time in accordance with the operating frequency of IC 51. For example, the period of an IC operating at 100 kHz, such as a switched power supply, is 10 μsec. In this case, it is preferable to apply a first AC signal and a second AC signal at the same frequency for one period or longer, preferably 10 periods, that is, about 100 μsec. Since the frequency is an analog value, this method can be employed for a particular frequency band, but in general, it is preferable to perform exhaustive measurement by setting bandwidths described below. In other words, when signal generation unit 10 is such a type that can set bandwidths, measurement is performed by setting a plurality of bandwidths. For example, signal generation unit 10 outputs a first AC signal and a second AC signal in a bandwidth with a 1 kHz interval up to 1 MHz, a bandwidth with a 1 MHz interval up to 100 MHz, and a bandwidth with a 10 MHz interval up to 1 GHz. When the bandwidth is as narrow as a few kHz to a few 100 kHz and signal generation unit 10 can generate a first AC signal and a second AC signal only frequency by frequency, the IC noise immunity may be measured while signal generation unit 10 sweeps the frequency of the first AC signal and the second AC signal. However, even in that case, IC 51 does not always malfunction immediately. Then, it is preferable that signal generation unit 10 outputs a first AC signal and a second AC signal with one frequency, for 10 or more periods per bandwidth, or by making the sweeping speed of the first AC signal and the second AC signal 10 or more times slower than the operating frequency of IC 51.

### (Determination Device)

Determination device 70 detects a malfunction by the first AC signal and the second AC signal applied as noise by first probe 40 and second probe 41. The simplest form of determination device 70 is, for example, a device having a pilot lamp or a speaker to indicate that the electronic equipment fails. Such a device makes sound or allows the lit lamp to turn off, or turn on, or blink when the electronic equipment fails. In particular, when IC 51 under test and the above device indicating failure are mounted, an additional device is unnecessary.

IC 51 under test or an IC directly or indirectly connected to the target under test and having a function of detecting a malfunction may transmit a signal indicating a malfunction to an external personal computer (PC) or the like via a cable through a connector such as a universal serial bus (USB) connector. Such an IC may transmit a signal indicating a malfunction wirelessly or via radio waves or sound waves such as ultrasound, rather than via a cable. However, unless a determination device inside IC 51 operates normally, a false determination may be made even when IC 51 is malfunctioning. Further, even when the determination device inside IC 51 operates normally, it may take time for IC 51 to determine a malfunction, leading to a false result.

FIG. 3 is a diagram illustrating a configuration example of determination device 70.

Determination device 70 includes a measuring unit 71, a computing unit 72, and a display unit 73. A typical one of such a determination device 70 is an oscilloscope or a real-time spectrum analyzer. A measurement cable 60 is directly connected to IC 51. Measurement cable 60 can be employed when IC 51 has a connector that detects an abnormal signal and outputs a certain output signal. On the other hand, when IC 51 does not have such a connector, determination device 70 can determine a malfunction of IC 51 by observing the output terminal of IC 51, an output of wiring connected to the output terminal, or change in output signal by an external signal. The terminal measured may be not only the output terminal but also the input terminal or the input/output terminal, but limiting to the output terminal and the input/output terminal can reduce the measurement time. Alternatively, determination device 70 may determine a malfunction by change in operative state of an IC different from the IC that is connected to IC 51. For example, when IC 51 is a power supply IC, determination device 70 may determine a malfunction state of the power supply IC by monitoring the operating state of another IC, such as a CPU or FPGA, supplied with electricity from the power supply IC to operate. A target to which noise is applied and a target whose malfunction state is monitored are not necessarily arranged on the same substrate. For example, when printed circuit boards are connected by PHYs, determination device 70 applies noise to the PHY of one printed circuit board and monitors the operating state of the PHY of the other printed circuit board to determine a malfunction state of the PHY to which noise is applied. Further, when a device A propagates radio, ultrasonic, or optical signals through air, determination device 70 may monitor the operating state of the device A, based on the operating state of a device B receiving the signal.

A contact-type high-impedance probe such as a single-ended passive probe, a field effect transistor (FET) probe (called active probe), or a differential probe can be used as a probe used for measurement. Alternatively, a non-contact probe such as a current probe or a Rogowski coil can be used as a probe used for measurement. Further, when a signal is received, a device with an optical probe such as an optical electric field probe or an E/O converter may be used to reduce the effect of distortion of an output signal by a probe. However, an output signal of IC 51 is not only an electrical signal but may be image, sound, vibration, heat, light, or the like. An output signal of IC 51 may be an abnormal operation of peripheral equipment connected to IC 51. In particular, in a case of an IC outputting direct current, the device as described above is not always necessary and a DC voltage may be measured by a tester.

Display unit 73 is a monitor of an oscilloscope or a tester. When determination device 70 does not have display unit 73 (monitor), determination device 70 may be connected to a PC or the like to make observation using the PC.

### (Measurement Method)

An example of the measurement method using probes will be described below.

When the return path of wiring on printed circuit board 50 is a single-ended signal line serving as the ground of printed circuit board 50, a contact or non-contact probe may be connected to an output position of IC 51. The measurement described above requires a measurement instrument. An oscilloscope is most preferable because temporal change can be observed, and when an output is not sufficient or too large, a preamplifier, an attenuator, a filter (low-pass filter, high-pass filter, band-bass filter, or a band-reject filter) or a DC cut may be used. In addition to an oscilloscope, a real-time spectrum analyzer can be used to capture temporal change with a large dynamic range (for example, 16 bit) even in a high frequency bandwidth such as GHz band. Further, when the behavior of IC 51 when noise is applied and the frequency characteristics at a time of malfunction are known in advance, the temporal change may be observed in a zero span mode of a spectrum analyzer. The terminal outputting an output signal of IC 51 may be the only terminal of IC 51 to observe a malfunction. This is because most of the causes of malfunction are attributable to change by noise mixed into an output signal or that IC 51 itself fails to output a desired signal. Determination device 70 may perform Fourier transform or short-time Fourier transform on an output signal of IC 51.

When noise is applied to IC 51 to cause a malfunction or abnormality of IC 51, it is preferable to immediately stop output of signal generation unit 10 or reduce the amplitude of an output signal. Different measures are taken depending on a state of IC 51 and a state of firmware written into IC 51. For IC 51 capable of auto recovery, an output of determination device 70 may be observed after auto recovery of IC 51, the result is fed back, and output of a signal of signal generation unit 10 may be resumed.

When IC 51 is unable to recover automatically, it is necessary to power off and restart IC 51 under test. When a peripheral circuit or another printed circuit board is connected to IC 51 under test, it is preferable to restart the equipment including IC 51. In some equipment, IC 51 does not always start operation immediately after restart. Therefore, it is preferable to wait until IC 51 starts operation after the power supply and driving software are started, and subsequently restart the equipment after checking whether IC 51 returns to a state before the malfunction, using determination device 70. When IC 51 is restarted but does not return to normal operation, the equipment is broken and therefore it is preferable to resume measurement with new equipment or issue an alert to prompt the operator to replace the equipment.

It is preferable to stop output of signal generation unit 10 or reduce the amplitude of an output signal when a malfunction of IC 51 is detected. This is because the destruction of IC 51 is caused by heat generated by much current flowing through wiring and circuit components. One of the causes of a signal flow that causes the destruction as described above is current directly excited from first probe 40 and second probe 41 to IC 51. For example, when feedback wiring of a power supply IC malfunctions, much current per unit time can continue to flow, and generated heat becomes larger than dissipated heat to melt bonding wires inside IC 51, leading to destruction. For a similar reason, a power semiconductor may produce breakdown voltage, leading to destruction. For this reason, in measurement, an output voltage does not have to be increased until the equipment malfunctions, and measurement may be finished at a point of time when the output waveform of determination device 70 changes.

The amplitude and frequency of the first AC signal and the second AC signal output by signal generation unit 10, the position and orientation of first probe 40 and second probe 41, whether to determine a malfunction, and restarting of the equipment may be controlled by an automatic system to continuously perform measurement. In particular, an automatic system equipped with a robot arm may be used so that the distance from first probe 40 and second probe 41 to a target under test and the orientation considering the directivity of first probe 40 and second probe 41 are kept constant. To determine a malfunction before IC 51 under test is destroyed, it is preferable to gradually change an output voltage of signal generation unit 10 and observe change in output of determination device 70. Such control continuously performed by the automatic system enables early discovery of a malfunction of IC 51 under test, thereby stopping measurement in a condition (specifically, voltage and power) before destruction occurs. When a non-contact probe is used as the probe, it is necessary to keep a constant distance between IC 51 under test and the non-contact probe in order to fix the amount of spatial coupling with IC 51 under test. The repeatability of measurement can be increased by controlling movement of the non-contact probe by mechanical means. When a contact probe is used as the probe, the contact probe is not displaced from a terminal to be measured. This decreases the possibility of short-circuiting and enables safe measurement.

Each component in the present embodiment will be described in detail below.

### <Target Under Test>

It is preferable that IC 51 under test is in an operative state. Therefore, IC 51 mounted on printed circuit board 50 that operates upon power-on is an evaluation target. In power-off of IC 51, a semiconductor element included in IC 51 is also in a normally on state or a normally off state. When the semiconductor element is on, the semiconductor element has a low impedance. When the semiconductor element is off, the semiconductor element has a high impedance. The impedance of IC 51 is different between power-on and power-off of IC 51. In a case of a normally-on semiconductor element such as a semiconductor element using gallium nitride (GaN) which is one of wide band-gap semiconductors, the above impedances are reversed. In either case, change in frequency characteristics of IC 51 for the applied signal is unable to be accurately grasped, because the propagation path of the applied signal varies.

Thus, it is preferable to measure, for example, an evaluation board of IC 51, a prototype, or IC 51 mounted on a product. In particular, for those having a circuit rewritable by software, such as a field programmable gate array (FPGA), it is preferable that firmware is in a state closer to an actual product. For those externally rewritable, such as an evaluation board of IC 51, it is preferable to perform evaluation in a state close to an actual product.

A noise filter such as a normal mode choke coil, a common node choke coil, a line capacitor, a ground capacitor, or a dumping resistor and the length of wiring connected to an IC terminal may be different between a prototype and an actual product. Under such conditions, the resonance frequency and the like changes. However, according to the present embodiment, a voltage is applied only between the intended terminals of IC 51 to feed current, so that measurement is less likely to vary with conditions of external wiring and components of IC 51.

Noise applied to the inside of IC 51 may be calculated by measuring the impedance characteristics of a passive component, converting into an equivalent circuit including a parasitic component such as parasitic capacitance or residual inductance, and then performing post-processing of solving common series/parallel circuit equations. These processing may be performed by inputting the equivalent circuit to a circuit simulator and calculating noise applied to the inside.

IC 51 as a target to be evaluated includes an IC that requires feedback control, such as a switched power supply, a communication IC such as a physical layer (PHY) chip, a sensor, an external card reader accessible by a person, such as an SD memory card, an IC handling high-speed signals, such as a double data rate synchronous dynamic random access memory (DDR SDRAM) or a CPU, and an IC having special functions such as an application specific integrated circuit (ASIC) or FPGA. However, IC 51 is not limited to these and may be an IC not included in the above, such as a linear regulator.

### <Output Signal of Signal Generation Unit>

An example of how to use a test signal output from signal generation unit 10 will now be described.

In a first step, first probe 40 and second probe 41 for inputting a first AC signal and a second AC signal serving as test signals are manipulated and arranged near a desired IC 51 or a terminal of IC 51.

In a second step, the amplitude of the first AC signal and the second AC signal output by signal generation unit 10 is minimized, and the frequency of the first AC signal and the second AC signal is swept over 10 seconds, for example, from 100 kHz to 1 GHz. This is to make sure that a malfunction does not occur in IC 51.

In a third step, the amplitude of the first AC signal and the second AC signal output by signal generation unit 10 is gradually increased, and measurement is performed with a similar frequency band until the amplitude that causes a malfunction of IC 51. If a malfunction does not occur in IC 51, the positions of first probe 40 and second probe 41 are changed.

In a fourth step, if a malfunction occurs, the frequency band is changed while the amplitude of the first AC signal and the second AC signal output by signal generation unit 10 is fixed. The frequency band is swept 100 times every 10 MHz, for example, from 100 kHz to 1 GHz. If the frequency is swept for approximately 10 seconds per band, the measurement is finished approximately within 1000 seconds, that is, 15 minutes. The step size of the frequency band is 10 MHz, and if this size is sufficient, the examination ends here.

In a fifth step, to observe the minimum voltage at which a malfunction of IC 51 occurs in a smaller band, a malfunction determination is performed by changing the band and the applied voltage (amplitude) within the band in which a malfunction occurs as described above.

By performing the measurement above, the voltage (amplitude) causing a malfunction of IC 51 can be grasped for each frequency. An IC that takes time until a malfunction, such as a communication circuit, can be evaluated by applying a signal with 10 or more periods per frequency to a target under test in the above. This is because a communication circuit takes time until a malfunction is determined, due to a resend request or the like, and applying noise for a short time often does not cause a malfunction.

Further, additive white Gaussian noise (AWGN) that replicates the effects of a number of random processes in nature can be considered as a signal having a bandwidth, and such a signal may be output from signal generation unit 10. Signal generation unit 10 can output a signal having a certain bandwidth by pulse-modulating a sinusoidal wave. A vector signal generator E8267D available from Keysight Technologies can be used as an example of signal generation unit 10 that generates the above signal. When an output of signal generation unit 10 is small, an output of signal generation unit 10 may be amplified by an amplifier. When the frequency is approximately 50 MHz or less, a bipolar power supply can be used as signal generation unit 10. When signal generation unit 10 is a bipolar power supply, a constant voltage or a constant current can be injected into IC 51, irrespective of the impedance of first probe 40 and second probe 41.

Signal generation unit 10 is a voltage source in the present embodiment but a current source may be used. Signal generation unit 10 may be a power source in a frequency band (for example 100 MHz or more) that should be considered as a distributed parameter. The applied voltage, the applied current, or the applied power can be converted to each other, because the frequency characteristics of the impedance of first probe 40 and second probe 41 can be uniquely determined. Thus, signal generation unit 10 may be any signal source and unit system.

### <First Probe and Second Probe>

First probe 40 and second probe 41 may be any probes such as electric field probes, magnetic field probes, or probes that can transmit and receive both of an electric field and a magnetic field. However, since the distance between terminals is approximately 100 μm in some ICs 51, it is preferable that the size of the application sections of first probe 40 and second probe 41 is equivalent to the distance between terminals. When the applied voltage and the applied current from signal generation unit 10 are high, the wiring that constitutes first probe 40 and second probe 41 should have a current capacity and be capable of feed the maximum rating current. When a common copper wire is used as wiring, current of approximately 1 A per mm² (square millimeters) can be fed, although it varies with conductivity and use environment. The distance between the coaxial core and the outer conductor of first probe 40 and second probe 41 needs to be an insulation breakdown distance or more. A typical insulation breakdown distance is approximately 1 kV per distance of 1 mm. More specifics comply with Paschen's law or modified Paschen's Law, and it is a reference value because the repeatability of insulation breakdown voltage is not high and the structure is attributable. In particular, when there is a sharp section between the coaxial core and the outer conductor, it is further necessary to increase the insulation breakdown distance, and typically an insulation breakdown voltage is used considering a safety factor (for example 3 or more).

According to the present embodiment, since a current path can be created by first probe 40 and second probe 41, the impedance between measurement points is reduced and the first AC signal and the second AC signal are easily mixed into a target under test. As a result, the voltage, current, and power of the first AC signal and the second AC signal output by signal generation unit 10 can be reduced and consequently first probe 40 and second probe 41 can be downsized. Furthermore, downsizing of first probe 40 and second probe 41 can reduce the size of the section of first probe 40 and the section of second probe 41 arranged in proximity to IC 51 or a terminal of IC 51. As a result, the positional resolution of the application section can be improved compared with conventional methods. To obtain the same applied voltage, first probe 40 and second probe 41 may be kept apart from a target under test so that the effect of the probes on the target under test can be reduced.

An example of the probe in which the section brought in proximity can be reduced is a coaxial probe as an electric field probe and a loop probe as a magnetic field probe.

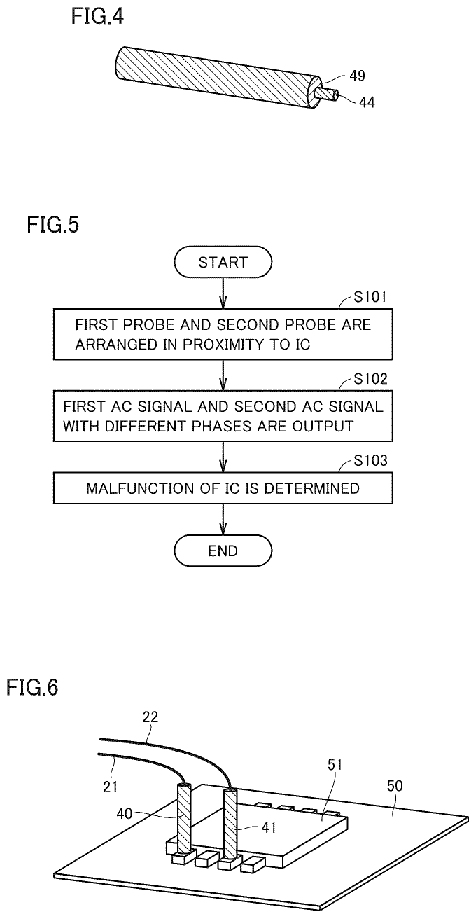

FIG. 4 is a diagram illustrating an example of a coaxial probe.

When the coaxial probe is an electric field probe, a core 44 of a thin coaxial or semi-rigid cable protrudes a few hundreds μm to a few mm from an outer conductor 49. This coaxial probe does not allow current to flow and can have a thinner core and therefore can be downsized. For example, in a case of a thin coaxial with a characteristic impedance of 50Ω, the thickness of core 44 can be 40 μm in diameter and the diameter of outer conductor 49 can be 200 μm. As a result, the coaxial probe can be arranged in the vicinity of even a minute terminal of IC 51 so that noise can be applied only to a particular terminal of IC 51. In a case of a semi-rigid cable, the thickness of core 44 can be 0.1 mm in diameter and the diameter of outer conductor 49 can be 1 mm or less. A probe may be attached to a tip end of a thin coaxial, semi-rigid cable, or coaxial cable.

When the coaxial probe is a magnetic field probe, a loop structure can be formed between core 44 and outer conductor 49, and therefore it can be made easily using the above thin coaxial or semi-rigid cable. However, the wiring needs to satisfy a current capacity as described above.

It is preferable that the distance between first probe 40 and second probe 41 and IC 51 under test or a terminal of IC 51 is small. For example, it is preferable that the distance is 1 mm or less. When a conductor portion is exposed at the tip end of first probe 40 and second probe 41, it is preferable that the conductor portion is covered with a dielectric to prevent electrical continuity even when coming into contact with a copper foil on printed circuit board 50. When first probe 40 and second probe 41 covered with dielectric are used, or a surface of a target under test is insulated, it is preferable to perform measurement by bringing first probe 40 and second probe 41 into contact with the insulating material on the surface of IC 51 under test. For example, in a case of an insulating material such as Kapton tape, the resolution of the application position can be improved by approximately 10 μm to 100 μm.

FIG. 5 is a flowchart illustrating the procedure of an IC noise immunity detection method in the first embodiment.

At step S101, first probe 40 and second probe 41 are arranged in proximity to IC 51.

At step S102, signal generation unit 10 outputs a first AC signal and a second AC signal with different phases as noise.

At step S103, determination device 70 determines whether IC 51 is malfunctioning, based on a state of IC 51.

FIG. 6 is a schematic diagram of a first measurement method in the first embodiment.

First probe 40 is arranged in the vicinity of one terminal of IC 51, and second probe 41 is arranged in the vicinity of another terminal of IC 51. Signal generation unit 10 can apply noise between two terminals of IC 51 by outputting the first AC signal and the second AC signal.

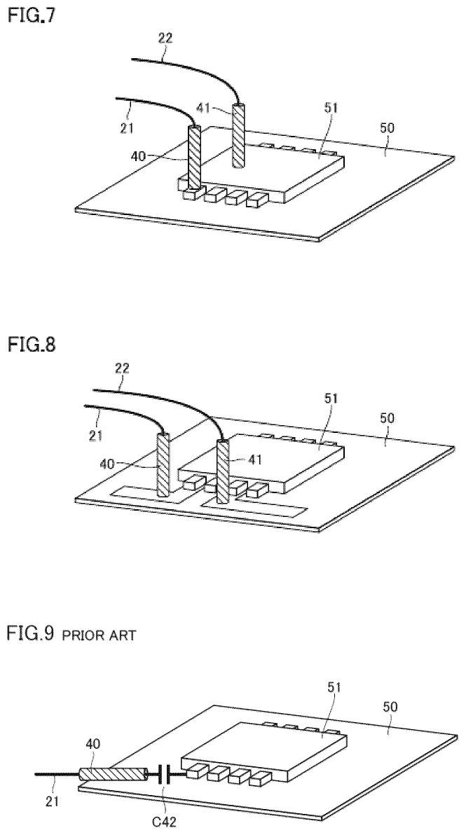

FIG. 7 is a schematic diagram of a second measurement method in the first embodiment.

First probe 40 is arranged in the vicinity of a terminal of IC 51. Second probe 41 is arranged in the vicinity of a semiconductor element or a bonding wire inside IC 51. This method is an effective method for a ball grid array (BGA) type in which a terminal of IC 51 is hidden under the board. This method can apply a potential difference between signal wiring and a GND terminal of the BGA-type IC 51.

FIG. 8 is a schematic diagram of a third measurement method in the first embodiment.

First probe 40 and second probe 41 are each arranged on wiring on printed circuit board 50 connected to a terminal of IC 51. Noise can be applied to the wiring on printed circuit board 50 connected to a terminal of IC 51. In this method, noise can be applied to wiring connected to a terminal of IC 51 when the terminal of IC 51 is small or when the terminal of IC 51 is not seen directly on the printed circuit board surface, as in the BGA type.

The combinations of probe positions in FIG. 6 to FIG. 8 illustrate an example of the noise application methods and are not limited to those illustrated here, and any combination can be employed.

Further, when it is desired to reduce the measurement conditions to simplify evaluation, the section to which the first AC signal and the second AC signal are injected from signal generation unit 10 is an input terminal or an input/output terminal of IC 51 under test, and the section from which an output signal of IC 51 is detected is an output terminal or an input/output terminal of IC 51 under test. For a single-ended signal, one probe is arranged in the vicinity of the GND terminal of IC 51 under test and the other probe is arranged in the vicinity of a signal terminal of IC 51 under test, whereby the number of combinations can be reduced and evaluation of IC 51 can be performed efficiently.

The section to which a signal is externally applied may be limited to an input terminal or an input/output terminal. The reason for this is that these terminals have high sensitivity and have a configuration to detect a signal not having a threshold, such as an analog signal. On the other hand, the output terminal often does not have such a configuration and is often robust against noise with a protective circuit or the like to prevent a malfunction by an output signal from the output terminal itself.

It is preferable to change the orientation of the probe such that the amount of coupling with the target under test is maximized. In a case of a loop probe which is a kind of magnetic field probe, the amount of noise application to a target can be maximized by maximizing the amount of coupling by setting the loop surface parallel to at least one of the orientation of the terminal of IC 51 and the orientation of wiring. In a case of a coaxial probe or a patch probe, the amount of noise application to a target can be maximized by maximizing the amount of coupling by arranging the probe at the right angle at which the area facing the target under test is largest and such that the distance to the target under test is smallest. Maximizing the amount of coupling in this way can reduce the output of signal generation unit 10, thereby downsizing first probe 40 and second probe 41. The amount of coupling for a known target under test may be grasped in advance and the amount of coupling may be corrected.

### <Determination Device>

Determination device 70 preferably detects a malfunction of the entire electronic equipment under test. The reason is that a malfunction of only a certain IC does not cause a problem unless the electronic equipment under test malfunctions. However, when only the overall characteristics are observed, it is difficult to detect a sign of malfunction of the target under test, possibly leading to a malfunction of the target under test. Thus, it is preferable that signal generation unit 10 gradually increases an output voltage and determination device 70 observes an output waveform of IC 51 to which a signal is applied while measuring the overall malfunction.

However, in addition to malfunction, only a sign leading to a malfunction may be measured. Specifically, determination device 70 observes an output signal when a signal is externally applied, and performs measurement with a condition where the voltage and power of the applied signal and the frequency are changed. Change in output waveform can be observed by the applied signal, and a malfunction often occurs in a condition in which the change is steep.

In order to measure a state of IC 51, a non-contact probe such as an electromagnetic field probe (electric field probe or magnetic field probe), a current probe (current probe or Rogowski coil), or an optical electric field probe can be used. Thus, the electromagnetic environment of a target under test can be less affected. The measurement with such a non-contact probe is effective when the internal impedance of a target under test is high, as is the case with an IC terminal receiving an input signal. Examples include feedback wiring of a switched power supply, a CPU to which an output terminal of a crystal oscillator is connected, and an input terminal of a memory (DDR).

Further, a probe for measurement may have directivity, in the same manner as first probe 40 and second probe 41 for noise application. Specifically, it is preferable to change the orientation of the probe for measurement such that the amount of coupling with the target under test is maximized. For example, in a case of a loop probe, the amount of coupling can be maximized by setting the loop surface parallel to the orientation of a terminal of IC 51 or the orientation of wiring.

### <Conventional Measurement Method>

For reference, a direct power injection (DPI) method which is an example of a conventional method of measuring noise immunity of an IC will be described.

FIG. 9 is a schematic diagram of a conventional measurement device. As shown in FIG. 9, a coaxial cable 21 connected to signal generation unit 10 is arranged in the vicinity of IC 51. A capacitor C42 of 1000 pF is arranged between the core of coaxial cable 21 and a terminal of an IC under test.

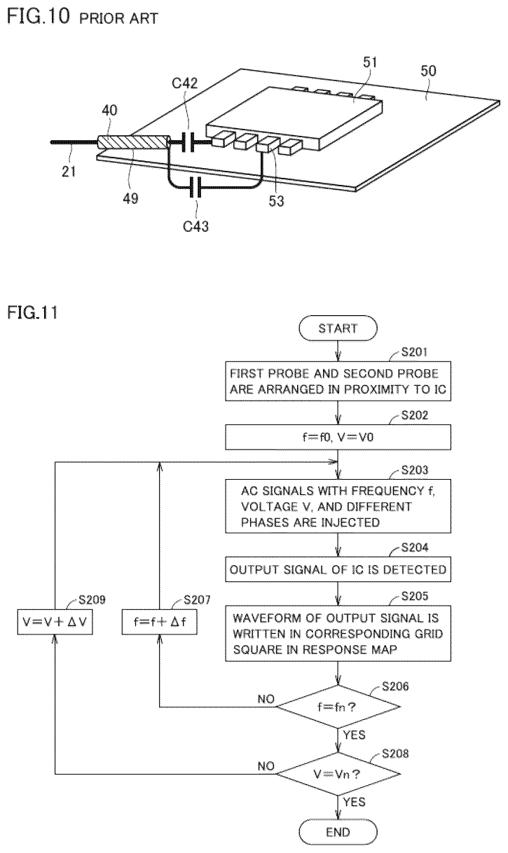

FIG. 10 is a schematic diagram of another conventional measurement device. As shown in FIG. 10, in addition to capacitor C42 between the core of coaxial cable 21 and the terminal of IC 51, a capacitor C43 is arranged between a GND terminal 53 of IC 51 and an outer conductor 49 of coaxial cable 21. This setting can make a structure that allows noise propagated from capacitor C42 to flow through capacitor C43, thereby achieving a characteristic similar to that of the method described in the present embodiment. Capacitor C42 and capacitor C43 are physical capacitors such as multilayer ceramic capacitors and are not capacitors of parasitic capacitance.

Unfortunately, when the GND potential serving as a reference potential of printed circuit board 50 is different from that of outer conductor 49 of the coaxial cable, the result is different from that of the present embodiment. In the present embodiment, since the outer conductor of the coaxial cable and GND of printed circuit board 50 are not connected to each other, measurement is possible even when there is a potential difference between them. On the other hand, in the conventional method, when they have different potentials, a signal propagates from one conductor to the other conductor. As a result, measurement is performed in a condition different from the condition when IC 51 operates normally. Furthermore, only attaching a probe injecting no signal may cause a malfunction or IC 51 may not be activated. For example, when printed circuit board 50 operates on an internal battery such as a battery and signal generation unit 10 is connected to a commercial power supply, their GND potentials including DC bias do not always match. When the electronic equipment is connected to a commercial power supply or when it is grounded, the same potential is attained as direct current, but as alternating current, the reference potential in the electronic equipment does not always have the same potential as the ground due to a parasitic component. Therefore, in many cases, it is difficult to operate the target under test normally by connecting GND of the probe and the electronic equipment under test. The present embodiment can eliminate such a factor causing a malfunction and therefore can perform measurement similarly on any IC or printed circuit board, compared with the conventional method.

### Second Embodiment

The present embodiment relates to a method of determining a malfunction of an IC.

The most obvious malfunction of electronic equipment is that the equipment fails to operate. However, the malfunction also includes that the electronic equipment that should stop starts operation, that the electronic equipment momentarily stops, or a signal is delayed. In other words, malfunction is that abnormality can be determined when an output of the electronic equipment is received by a person or another electronic equipment. One of methods of replicating this malfunction in a test environment is to measure the presence/absence of a malfunction using voltage, power, frequency, frequency bandwidth, continuous wave or pulsed wave of the first AC signal and the second AC signal output by signal generation unit 10, as parameters.

However, the above method can be used only in a state in which implementation of hardware such as a printed circuit board and implementation of software for controlling them are finished and electronic equipment is completed. Even when a malfunction of IC 51 is found in this state, in which at least a prototype is completed, it is often impossible to make a major modification such as replacement of ICs. The present embodiment provides a method of evaluating an IC at a stage before electronic equipment is completed.

Specifically, in the noise immunity measurement method in the present embodiment, in an operative state of electronic equipment with IC 51 under test, a response map that represents the waveform of an output signal in each frequency and each amplitude is created by changing the frequency and amplitude of the first AC signal and the second AC signal externally applied and measuring an output signal of IC 51.

FIG. 11 is a flowchart illustrating the procedure of an IC noise immunity detection method in a second embodiment.

At step S201, first probe 40 and second probe 41 are arranged in proximity to IC 51.

At step S202, signal generation unit 10 sets a frequency f to an initial value f0 and an amplitude V to an initial value V0.

At step S203, signal generation unit 10 outputs a first AC signal and a second AC signal with frequency f and amplitude V and with different phases as noise. The first AC signal and the second AC signal are injected into IC 51 by first probe 40 and second probe 41.

At step S204, determination device 70 detects an output signal of IC 51.

At step S205, determination device 70 writes the waveform of the output signal into a grid square corresponding to frequency f and amplitude V in the response map.

At step S206, if frequency f is exit value fn, the process proceeds to step S208, and if frequency f is not exit value fn, the process proceeds to step S207.

At step S207, signal generation unit 10 increments frequency f by step size Δf.

At step S208, if amplitude V is exit value Vn, the process ends, and if amplitude V is not exit value Vn, the process proceeds to step S209.

At step S209, signal generation unit 10 increments amplitude V by step size ΔV.

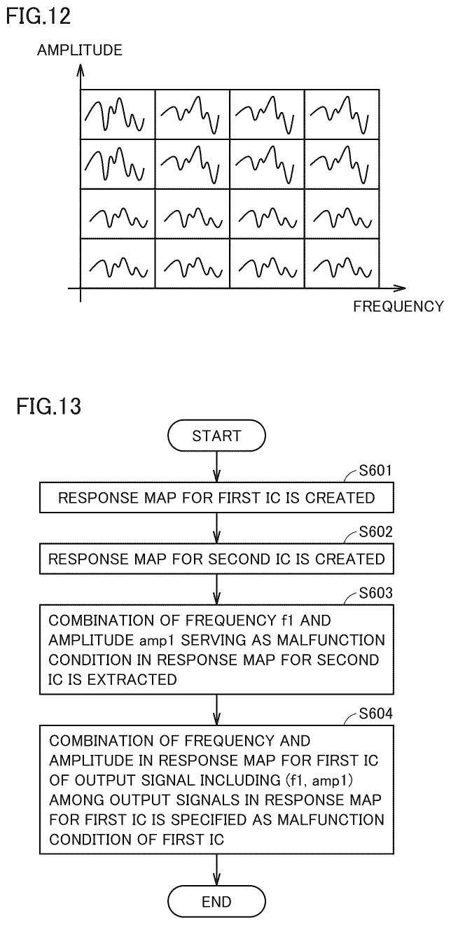

FIG. 12 is a diagram illustrating an example of a response map in the second embodiment. The horizontal axis in FIG. 12 represents the frequency of the first AC signal and the second AC signal input to the input terminal of IC 51. The vertical axis in FIG. 12 represents the amplitude of the first AC signal and the second AC signal input to the input terminal of IC 51. The horizontal axis and the vertical axis are divided to form a grid. The response map includes an output waveform in each square of the grid. This output waveform indicates the frequency characteristics. The frequency on the horizontal axis of the response map is depicted at regular intervals but not necessarily at regular intervals and may be depicted by antilogarithms or logarithms. The amplitude on the vertical axis of the response map is also depicted at regular intervals but not necessarily at regular intervals and may be depicted by antilogarithms or logarithms. The amplitude on the vertical axis varies with the kinds of signal generation unit 10, first probe 40 and second probe 41. The amplitude on the vertical axis may be the amplitude of any signal that can be injected into an IC as an electrical signal, such as voltage, current, power, electric field, or magnetic field. The input method and the output method may use a contact probe or may use a non-contact probe. However, when a contact probe is used, the measured output waveform is preferably a signal waveform in which an internal circuit component in the probe is corrected, and when a non-contact probe is used, a signal waveform corrected by an antenna factor is preferable. Further, when a circuit component other than IC 51, such as a noise filter or a coil, is mounted on a terminal of IC 51, it is preferable that the frequency characteristics of such a component is measured in advance and the measured output waveform is corrected into a signal waveform in the absence of such a component.

In FIG. 12, the number of squares of the grid are 4×4 both in the frequency axis and the amplitude axis. However, the embodiment is not limited to this and the grid may be divided by any number. Each axis needs not be divided at regular intervals and the grid may be divided minutely in particular in the vicinity of a frequency and voltage at which a malfunction is likely to occur. In such a band in which a malfunction is likely to occur, when how a malfunction occurs varies with bandwidth, the squares of the grid may overlap. Further, the frequency axis may be displayed by logarithms and the amplitude axis may be displayed by antilogarithms. In this case, it is also preferable that signal generation unit 10 changes an output signal in logarithms for the frequency direction and in antilogarithms for the amplitude direction. By using logarithms in the frequency direction, general characteristics can be grasped from a low-frequency band to a high-frequency band. The amplitude direction is often proportional to antilogarithms, for example, threshold voltages of ICs, antilogarithms can be used in most cases, though depending on the characteristics of ICs.

When a malfunction can be determined with a single IC, the frequency and amplitude causing a malfunction is identified with a single response map. However, those that cannot be considered as malfunctions occur. For example, an output voltage changes with an external signal as in a switched power supply IC. A response map for a first IC serving as a target under test may be created, and a response map for a second IC connected to the first IC may be created. The first IC is an IC whose malfunction is unable to be determined alone, such as a switched power supply IC. The second IC is an IC whose malfunction can be determined.

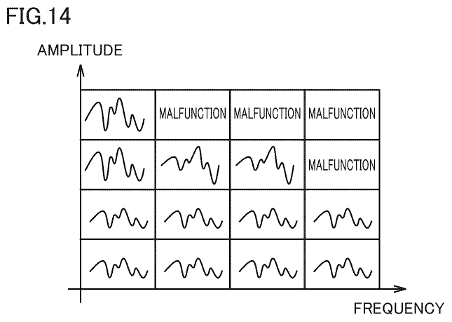

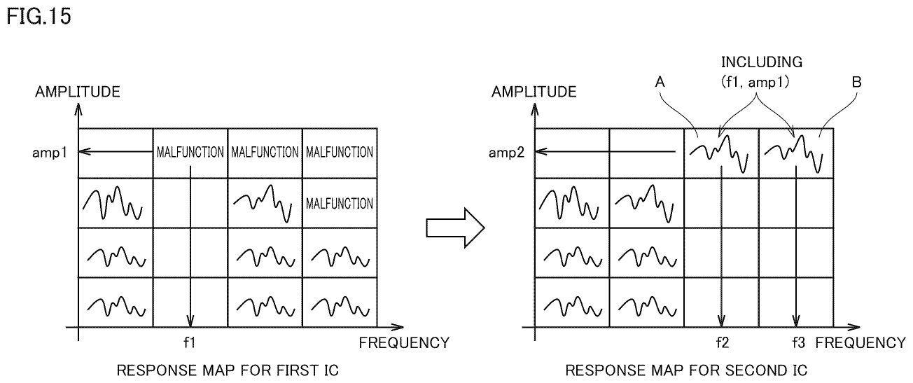

FIG. 13 is a flowchart illustrating the procedure of a method of determining a malfunction condition using two response maps. FIG. 14 is a diagram illustrating a response map for a second IC. FIG. 15 is a diagram for explaining a method of specifying a malfunction condition using two response maps.

At step S601, a response map for a first IC is created.

At step S602, a response map for a second IC connected to the first IC is created.

At step S603, a combination of frequency (f1) and amplitude (amp1) serving as a malfunction condition in the response map for the second IC is extracted.

At step S604, among output signals in the response map for the first IC, a combination of frequency and amplitude in the response map for the first IC of an output signal including the extracted combination of frequency (f1) and amplitude (amp1) is specified as a malfunction condition for the first IC. As shown in FIG. 15, since the output waveform in a grid square A of the response map for the first IC includes amplitude (amp1) and frequency (f1), frequency f2 and amplitude amp2 in grid square A are specified as a malfunction condition of the first IC. Since the output waveform in a grid square B of the response map for the first IC includes amplitude (amp1) and frequency (f1), frequency f3 and amplitude amp2 in grid square B are specified as a malfunction condition of the first IC.

If a malfunction determination is unable to be made with the second IC, a malfunction is determined with a third IC connected to the second IC. As previously mentioned, this method is only applied when the presence/absence of malfunction of the first IC is unable to be determined. If a malfunction can be determined with the first IC alone, this method is not necessarily used. However, as described above, since the second IC may malfunction even when the first IC does not malfunction, this method can also be used even when the evaluation can be made with an IC alone.

In the response map, it is preferable to divide the frequency band minutely, for example, set every 1 Hz, but the measurement time is enormous and it is difficult to measure within a realistic time period. Then, the first AC signal and the second AC signal output by signal generation unit 10 are set as signals having a bandwidth of at least 1 kHz, thereby reducing the measurement time. In a standard test such as CISPR11, a bandwidth of 9 kHz or more is often used, but a band causing a malfunction can be grasped more accurately by setting a narrower bandwidth.

The measurement time can be reduced by outputting continuous waves in which one or more sinusoidal waves are superimposed on each other from signal generation unit 10. Also in this case, the response map may be formed into a grid, and the waveform of an output signal may be written into a grid square with a corresponding condition.

The response map can also be created by outputting a trapezoidal signal with at least fixed amplitude, rising time, falling time, period, on time, and duty ratio from signal generation unit 10. For example, for an IC that may malfunction with power, signals with wide bands need to be simultaneously injected, and a trapezoidal waveform having such a wide frequency band can be used.

A response map for a signal similar to an impulse signal can also be generated by conduction transient testing (FET/B testing) or the like. In this case, an output signal to be written into each grid square of the response map is not necessarily the frequency characteristics and may be a time signal using an oscilloscope or a spectrogram using a real-time spectrum analyzer. Determination device 70 may find the frequency characteristics by Fourier transform of the above trapezoidal wave. Signal generation unit 10 may apply a wide-band signal to a target under test using a waveform having a Gaussian distribution with a bandwidth from the center frequency, instead of a trapezoidal wave.

Conventionally, when electronic equipment includes a plurality of ICs, it is necessary to evaluate a malfunction condition for a combination of these ICs. Therefore, when the combination and the connection relation of ICs are changed, a malfunction condition needs to be reevaluated. In the present embodiment, a response map is created in advance for each IC to eliminate the need for reevaluation of a malfunction condition even when the combination and connection relation of ICs are changed. By preparing each response map in advance, the presence/absence of occurrence of malfunction can be evaluated quantitatively at a design early stage when design change is easy.

### Modification of Second Embodiment

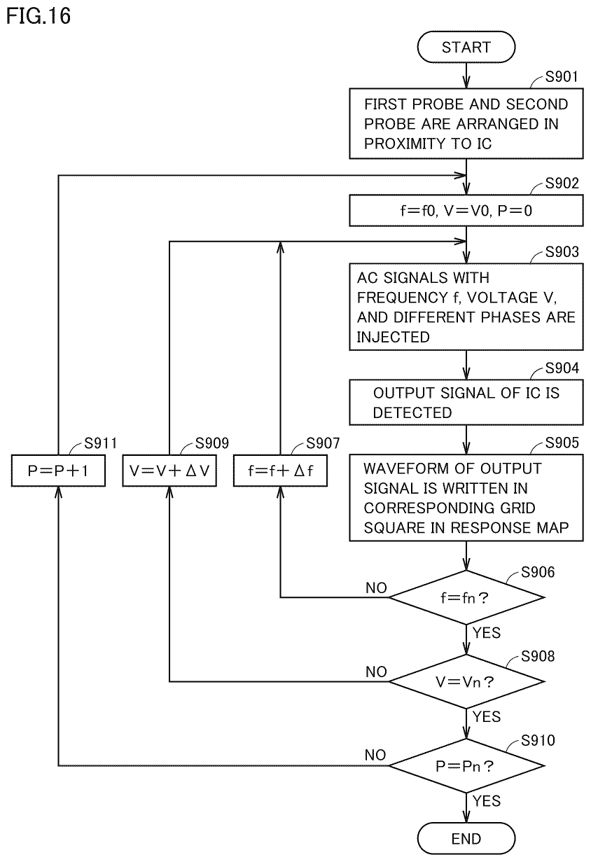

FIG. 16 is a flowchart illustrating the procedure of an IC noise immunity detection method in a modification of the second embodiment.

At step S901, first probe 40 and second probe 41 are arranged in proximity to IC 51.

At step S902, signal generation unit 10 sets terminal number P of IC 51 to 0, frequency f to initial value f0, and amplitude V to initial value V0.

At step S903, signal generation unit 10 outputs a first AC signal and a second AC signal having different phases with frequency f and amplitude V as noise. The first AC signal and the second AC signal are injected by first probe 40 and second probe 41 into a terminal with terminal number PN of IC 51.

At step S904, determination device 70 detects an output signal of IC 51.

At step S905, determination device 70 writes the waveform of the output signal into a grid square corresponding to frequency f, amplitude V, and terminal number P in the response map.

At step S906, if frequency f is exit value fn, the process proceeds to step S908, and if frequency f is not exit value fn, the process proceeds to step S907.

At step S907, signal generation unit 10 increments frequency f by step size Δf.

At step S908, if amplitude V is exit value Vn, the process proceeds to step S910, and if amplitude V is not exit value Vn, the process proceeds to step S909.

At step S909, signal generation unit 10 increments amplitude V by step size ΔV.

At step S910, if terminal number P is exit value Pn, the process ends, and if terminal number P is not exit value Pn, the process proceeds to step S911.

At step S911, signal generation unit 10 increments terminal number P by 1.

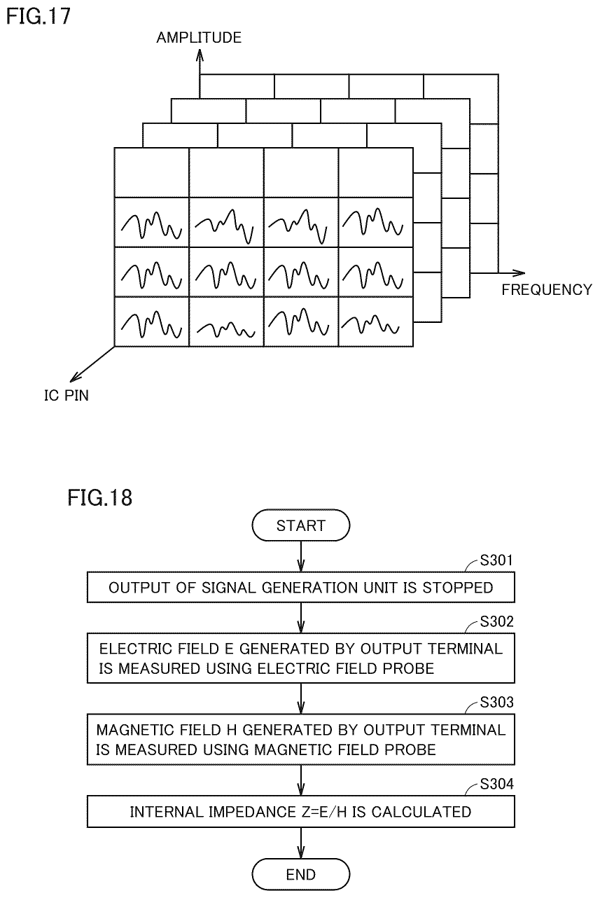

FIG. 17 is a diagram illustrating an example of a response map in a modification of the second embodiment.

In the response map in a modification of the second embodiment, the waveform of an output signal is written, in a combination of the frequency of an AC signal injected into the IC, the amplitude of the AC signal injected into the IC, and a terminal into which the AC signal is injected in the IC.

### Third Embodiment

The present embodiment relates to measurement of the internal impedance of the output terminal of IC 51.

A circuit is formed in the inside of each of an IC and a terminal of the IC. The internal impedance varies among the terminals of the IC. For example, when the internal impedance of the input terminal is 0Ω, that is, close to a short-circuit, an excitation voltage is not produced in a circuit inside the IC and therefore the output is small, and in a case of a circuit malfunctioning due to a voltage, a malfunction is less likely to occur. On the other hand, when the internal impedance of the input terminal is, for example, 1 MΩ, that is, close to open, an excitation voltage increases and therefore the output is larger. Typically, the internal impedance of a terminal of the IC is intermediate between short-circuit and open. The internal impedance of the IC has not only a resistance component but also an inductance component, a capacitance component, and a non-linear component such as diode. Due to such characteristics of the internal impedance, the voltage amplitude generated by an externally applied signal inside the IC changes.

FIG. 18 is a flowchart illustrating the procedure of a method of measuring an internal impedance of an output terminal of an IC in a third embodiment.

At step S301, a state in which output of signal generation unit 10 is stopped is set.

At step S302, an electric field probe is arranged in the vicinity of an output terminal PO in which an output signal in the IC in the operative state does not change or changes periodically, and an electric field E generated by output terminal PO is measured by the electric field probe.

At step S303, a magnetic field probe is arranged at the same place as the place where the electric field probe is arranged, and a magnetic field H generated by output terminal PO is measured by the magnetic field probe.

The measured electric field and magnetic field may be converted into an electric field and magnetic field at the probe position, using an antenna factor of the electric field probe and an antenna factor of the magnetic field probe. In particular, since the electric field is used in the near field region (specifically, a region belonging to fresnel region or ultra-near field region and with approximately 1 to 3 wavelengths or less), it is preferable that an antenna factor is calculated for a known target under test such as a microstrip line when the distance to the target under test is different from a calibrated value of each probe.

At step S304, determination device 70 calculates impedance Z from electric field E and magnetic field H. Impedance Z can be considered as the internal impedance of output terminal PO of IC 51. For example, when the internal impedance of the IC is high, current does not flow and magnetic field H is small, whereas voltage rises and electric field E is large. As a result, impedance Z is a large value.

$$Z = E / H \qquad ( 1 )$$

For the sake of simplicity, given wiring connected only to IC1 and IC2, current flowing through the terminal of IC1 is equal to current flowing through the terminal of IC2. However, when the internal impedance of IC1 is different from the internal impedance of IC2, the voltage applied to the terminal of IC1 is different from the voltage applied to the terminal of IC2, and thus the electric field distribution in the vicinity of the terminal of IC1 is different from the electric field distribution in the vicinity of the terminal of IC2. That is, the excitation voltage of the one with the higher internal impedance becomes higher and the electric field becomes larger, whereas the excitation voltage of the one with the lower internal impedance becomes lower and the electric field becomes smaller. Based on this information and the magnetic field measured by the magnetic field probe, the internal impedance of the terminal of each IC can be predicted.

Further, when the frequency characteristics of the impedance of a component such as a dumping resistance connected to wiring between ICs are known or measurable, the impedance of the target under test can be determined using a circuit simulator or the like, considering the impedance characteristics, voltage division, and current division. The internal impedance of the IC can be calculated based on the rate of change obtained by intentionally implementing a known impedance on wiring.

The IC terminal can be connected to anything through wiring, but preferably a passive circuit for which the frequency characteristics of impedance can be measured. Specifically, when the circuit constant of a connection destination of the IC is known, simultaneous equations of current and voltage can be written with the internal impedance as the unknown, using an equivalent circuit. The frequency characteristics of the internal impedance can be estimated by solving the simultaneous equations as overdetermined equations using the least squares method, that is, by a solution method according to a generalized inverse matrix. On the other hand, when the circuit constant of a connection destination of the IC is unknown, the above method of finding an electric field and a magnetic field is carried out again, and with the internal impedance of each IC as the known, four simultaneous equations are written from the electric field and the magnetic field in each measurement result. The respective internal impedances can be estimated by solving the simultaneous equations as overdetermined equations using the least squares method. The measurement value is frequency data, and if the inside of the IC is composed of R, L, C, a theoretical solution may be calculated using an equivalent circuit model. The frequency characteristic is output so as to be fitted to a grid square for each frequency in the response map. However, when the grid is large, data may be stored as another matrix as the frequency characteristics.

A method of measuring the internal impedance of an IC using an electric field probe and a magnetic field probe has been described above. However, the embodiment is not limited to this. A probe that can acquire a value proportional to current or voltage if the characteristics of the probe is corrected, an optical electric field probe, a current probe, or the like may be used instead.

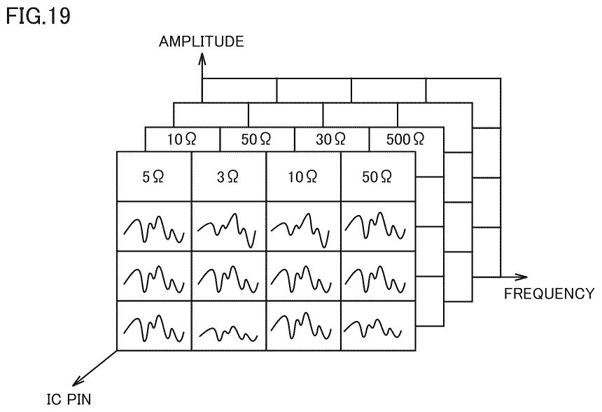

FIG. 19 is a diagram illustrating an example of a response map including a description of internal impedance. As shown in FIG. 19, when any IC is connected, the signal amplitude excited in each terminal of the IC can be calculated accurately by writing the internal impedance measured in each frequency into the response map. In this case, it is preferable to create a response map including the frequency characteristics of internal impedance in not only the output terminal but also all the terminals of the IC.

For example, such a response map can be used in the following case.

The internal impedance of a terminal of a first IC and the internal impedance of a terminal of a second IC connected to the terminal of the first IC are extracted from a response map. An input signal of the first IC when a malfunction voltage of the second IC is excited can be inversely estimated, using the internal impedance of the terminal of the first IC and the internal impedance of the second IC. Thus, the noise immunity for the first IC can be estimated. Since the internal impedance and the output waveform include frequency characteristics, a circuit simulator and a common optimization method can be used for inverse estimation calculation of an input signal of the first IC.

### Fourth Embodiment

The present embodiment relates to measurement of the internal impedance of the input terminal of IC 51.

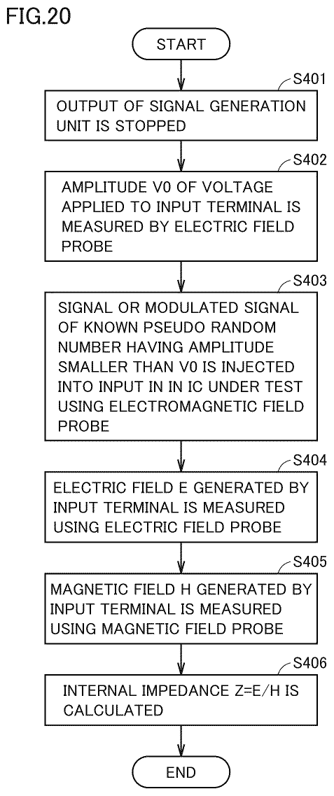

FIG. 20 is a flowchart illustrating the procedure of a method of measuring an internal impedance in a fourth embodiment.

At step S401, a state in which output of signal generation unit 10 is stopped is set.

At step S402, an electric field probe is arranged in the vicinity of an input terminal PI of an IC in the operative state, and amplitude V0 of the voltage applied to input terminal PI is measured in a non-contact manner by the electric field probe.

At step S403, signal generation unit 10 outputs a signal or a modulated signal of a known pseudo random number having amplitude V1 smaller than amplitude V0 of the measured voltage. For example, a signal or a modulated signal of a known pseudo random number is injected into input terminal PI of IC 51, using first probe 40. Amplitude V1 of a signal applied as noise is set to be smaller than V0, because it is obvious that IC 51 malfunctions if noise having the same amplitude as amplitude V0 of a signal input to input terminal PI is injected into input terminal PI. This can avoid malfunction of IC 51 due to noise.

At step S404, an electric field probe is arranged in the vicinity of input terminal PI of IC 51, and electric field E generated by input terminal PI is measured in a non-contact manner, using the electric field probe.

A measurement instrument for measuring a signal of the electric field probe is preferably an oscilloscope, a spectrum analyzer, or the like. The signal may be amplified by a preamplifier or the like or the signal may be attenuated by an attenuator, if necessary. Measurement is performed such that measurement conditions of the measurement instrument are satisfied by adjusting the distance between the target under test and the electric field probe.

At step S405, a magnetic field probe is arranged at the same place as the place where the electric field probe is arranged, and a magnetic field H generated by input terminal PI is measured by the magnetic field probe in a non-contact manner.

The measured electric field and magnetic field may be corrected to an electric field and magnetic field at the probe position, using an antenna factor of the electric field probe and an antenna factor of the magnetic field probe. In particular, since the electric field is used in the near field region (specifically, a region belonging to fresnel region or ultra-near field region and with approximately 1 to 3 wavelengths or less), it is preferable that an antenna factor is calculated for a known target under test such as a microstrip line when the distance to the target under test is different from a calibrated value of each probe. Determination device 70 may find voltage V from the measured electric field E and find current I from the measured magnetic field H.

At step S406, determination device 70 calculates impedance Z (=E/H) from electric field E and magnetic field H. Impedance Z can be considered as the internal impedance of input terminal PI of the IC. Determination device 70 may calculate impedance Z (=V/I) from voltage V based on electric field E and current I based on magnetic field H.

Further, the impedance of a desired IC may be found by circuit calculation by finding impedance Z by the above method for another IC connected to the terminal of the above IC 51 through wiring. The impedance of a desired IC may be estimated by circuit calculation by finding impedance Z by the above method, for a passive circuit component such as a resistor, capacitor, coil, or diode connected to the terminal of IC 51, at the input/output terminal of a passive circuit component.

In the circuit calculation, the impedance of the above IC or passive circuit is set as the unknown and solved as a voltage or current equation from the above measurement result, and the unknown can be calculated as an overdetermined equation if the measurement condition is equal to or greater than the unknown.

The above method is effective for a terminal of an IC that is receiving or outputting a signal, but is unable to measure a terminal that is not receiving a signal and a terminal that is not outputting a signal. In such a case, a method of estimating the internal impedance of IC 51 by externally applying a signal is used. However, if a voltage larger than the voltage of the terminal of IC 51 is externally input to measure the impedance, IC 51 itself malfunctions, and thus the internal impedance of IC 51 is unable to be measured. On the other hand, if an output signal of IC 51 is large, the externally applied signal is buried, and therefore the impedance is unable to be measured accurately. In the present embodiment, the internal impedance can also be estimated from the correlation between a transmission signal (that is, an output signal of signal generation unit 10) and a reception signal (that is, electric field E or magnetic field H detected by determination device 70), by using a modulated signal as used in wireless communication or by generating a known pseudo random number (a signal in which a receiver side knows a signal generated by a signal generator side, such as M-sequence signal).

The impedance in each frequency may be determined for each band having a bandwidth so as to be fitted to a grid square of the response map described in the second embodiment, and the result may be written into the response map.

### Fifth Embodiment

The present embodiment relates to a method of checking a malfunction by paying attention to temperature change of IC 51.

When noise is externally applied to IC 51 to cause a malfunction, the voltage of a semiconductor element inside IC 51 exceeds a threshold to cause a malfunction. For example, noise may be mixed into feedback wiring for monitoring the voltage of a switched power supply to cause an output voltage to change from the designed value or cause superimposition of noise on an output voltage. As a result, the equipment may be stopped or the stopped equipment may be started. Temperature change always occurs in IC 51. For example, when the equipment is stopped, the temperature decreases, whereas when the equipment is started, heat is generated. As for feedback wiring of a power supply, when decrease in output voltage by a signal of applied noise is detected, a process of increasing the output voltage is performed by increasing the Duty ratio. When increase in output voltage is detected, the output voltage is decreased by reducing the Duty ratio. When the output voltage changes, the output energy also changes, so that power consumption changes. Therefore, by observing the temperature of the target under test, it is possible to observe a malfunction without bringing a measurement instrument in proximity to the target under test and without affecting the measurement system at all.

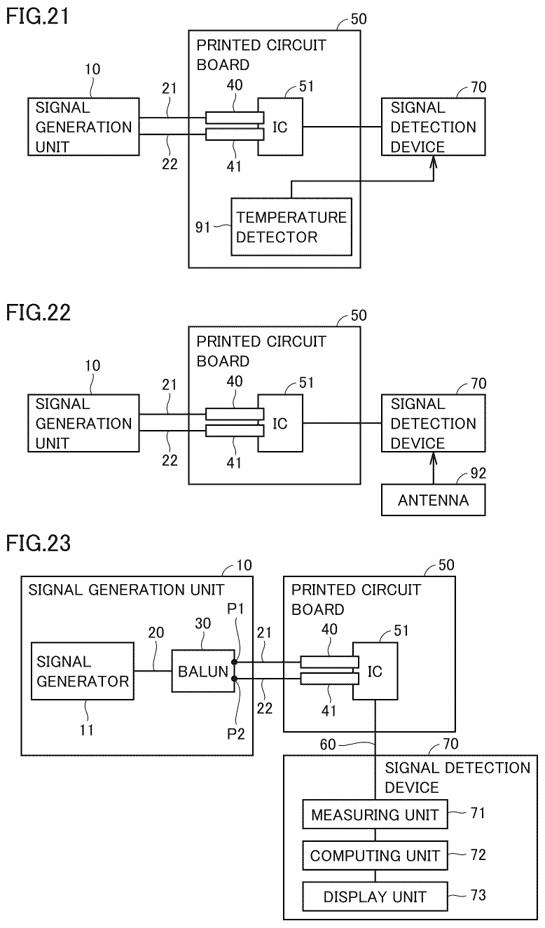

FIG. 21 is a diagram illustrating a configuration of an IC noise immunity detection device in a fifth embodiment.

The IC noise immunity detection device in the fifth embodiment includes a temperature detector 91.

Temperature detector 91 detects a temperature change of IC 51 or an IC different from IC 51 that is connected to IC 51. An infrared camera or a non-contact thermometer can be used as temperature detector 91. Thus, the temperature can be measured remotely in real time. Since it is necessary to observe particularly a temperature change, it is preferable that measurement is started after the target under test becomes thermally stable in an environment in which the temperature is constant with no wind. In such a target under test and measurement environment, the temperature is observed with the above infrared camera or non-contact thermometer by changing the amplitude and frequency of the first AC signal and the second AC signal externally applied by signal generation unit 10.

Determination device 70 determines whether IC 51 is malfunctioning, based on a temperature change of IC 51 or the IC different from IC 51 that is connected to IC 51. Although the temperature change varies depending on IC 51, determination device 70 may determine that IC 51 is malfunctioning, for example, when a temperature change of the IC of 5 degrees or more is detected. Since IC 51 abruptly becomes hot immediately before IC 51 is destroyed, signal generation unit 10 can stop output when temperature change of IC 51 is detected, thereby preventing destruction of IC 51.

### First Modification of Fifth Embodiment

FIG. 22 is a diagram illustrating a configuration of an IC noise immunity detection device in a modification of the fifth embodiment.

The IC noise immunity detection device in a modification of the fifth embodiment includes an antenna 92 instead of temperature detector 91.

Antenna 92 detects an electromagnetic wave emitted from IC 51. Antenna 92 is arranged at a considerable distance from IC 51.

Determination device 70 determines whether IC 51 is malfunctioning, based on change in reception voltage in antenna 92 in a frequency band other than the frequency band of the first AC signal and the second AC signal.

The considerable distance is, for example, a distance of approximately 1 m. Alternatively, the considerable distance may be a distance one wavelength or longer with respect to the frequency. For example, to measure a signal of 100 MHz, antenna 92 may be installed approximately 3 m away from IC 51. However, keeping such a distance reduces the S/N ratio and makes it difficult to observe a change in radio wave environment due to change in IC 51. In such a case, an antenna having high directivity, such as a parabolic antenna or a phased array antenna may be used as antenna 92. Since only relative change is required to capture a change of the state of IC 51, antenna 92 may be arranged at a distance one wavelength or shorter with respect the frequency. It is also preferable to perform in a shield room or shield tent, or an anechoic chamber isolated from disturbance noise of radio, television, or mobile phone.

### Sixth Embodiment

FIG. 23 is a diagram illustrating a configuration of an IC noise immunity detection device according to a sixth embodiment.

Signal generation unit 10 of the IC noise immunity detection device in the sixth embodiment includes a signal generator 11, a coaxial cable 20, and a balun 30.

Signal generator 11 and balun 30 are connected by coaxial cable 20.

Signal generator 11 generates a test signal that is electromagnetic noise. Signal generator 11 is, for example, a signal generator or a function generator.

Balun 30 generates a first AC signal and a second AC signal with equal amplitudes and a phase difference of 180 degrees, from a test signal generated by signal generator 11.

Balun 30 separates a test signal generated by signal generator 11 into differential signals (called differential mode or normal mode) or in-phase signals (called common mode). Balun 30 used in the present embodiment is a coupler called 180-degree hybrid coupler. Balun 30 can produce two AC signals with equal amplitudes and a phase difference of 180 degrees, from one test signal generated by signal generator 11. Power input to balun 30 is output from two ports, each outputting a half. Therefore, considering insertion loss, the power is ½ or less each. Since balun 30 is configured with an analog circuit, an in-phase signal of approximately −30 dB relative to the differential signal is generated, depending on the frequency and the internal circuit of balun 30.

Balun 30 is a common one used to make a dipole antenna. Since dipole antennas are also used as transmission antennas, there are many that can input a large current, a large voltage, or a large power required for signal application in the present embodiment. Further, signal generator 11 may have a band-pass filter or the like to output only a certain band.

Balun 30 has one input port and two output ports P1, P2. Output port P1 of balun 30 is connected to first probe 40 through first coaxial cable 21. Output port P2 of balun 30 is connected to second probe 41 through second coaxial cable 22. Thus, a signal output from signal generator 11 can be output as a differential signal produced between first probe 40 and second probe 41.

Signal generation unit 10, first probe 40, and second probe 41 constitute differential signal injecting means for injecting a differential signal to IC 51 on printed circuit board 50. To make a differential signal, it is necessary to make the electrical length from balun 30 to first probe 40 equal to the electrical length from balun 30 to second probe 41. A potential difference is produced between first probe 40 and second probe 41 to allow noise current to flow through IC 51 and printed circuit board 50.

Balun 30 is used for generating a differential signal and, in addition, is effective in protecting signal generator 11 and making the target under test less susceptible. As for protecting signal generator 11, in some targets under test, noise of the target under test is large and noise may be superimposed on signal generator 11 through probes 40, 41. By using balun 30, only a differential (normal) mode component of two probes 40, 41 is mixed into signal generator 11 through coaxial cables 21, 22. The in-phase component (common mode component) is consumed by a terminator (50Ω resistance is commonly used) of balun 30, loss inside balun 30, or reflection to probes 40, 41, and not mixed into signal generator 11. Signal generator 11 can be protected for such a reason. On the other hand, the measurement system is not susceptible for a similar reason. If a signal of printed circuit board 50 propagates to signal generator 11, a propagation path of a signal different from that in normal operation is formed. Such a propagation path is less likely to be produced because of the presence of balun 30, thereby reducing the effect on the measurement system.

### <Differential Signal>

In the differential signal in the present embodiment, the phases of two AC signals input to first probe 40 and second probe 41 are different by 180 degrees. For example, when a voltage with a certain frequency at a certain time is observed, the voltage applied to first probe 40 is +1 V and the voltage applied to second probe 41 is −1 V. More preferably, an electromagnetic field output from first probe 40 and an electromagnetic field output from second probe 41 may have equal amplitudes and opposite phases. In such a case, a potential difference occurs because an electric line of force is produced from first probe 40 toward second probe 41. As a result, current flows between first probe 40 and second probe 41. When wiring or a conductor such as an IC is present between first probe 40 and second probe 41, an electric line of force is produced via the conductor to transmit a potential difference between first probe 40 and second probe 41 to the conductor.

In the present embodiment, it is particularly preferable because the differential signals can produce a largest potential difference between first probe 40 and second probe 41.

When the electrical length from signal generation unit 10 to first probe 40 and the electrical length from signal generation unit 10 to second probe 41 are not equal because the length of first coaxial cable 21 and the length of second coaxial cable 22 are different, the difference between the phase of the first AC signal and the phase of the second AC signal is not 180 degrees. In such a case, a common mode signal is generated.

When a frequency of 1 GHz or more is measured using first coaxial cable 21 and second coaxial cable 22 of different kinds, it is necessary to make the electrical length of first coaxial cable 21 equal to the electrical length of second coaxial cable 22. In measurement of an electrical length, it is preferable to measure S11 (reflection characteristic) using a network analyzer or to measure a time domain reflection using an oscilloscope having the time domain reflectometry (TDR) function, grasp the electrical length, and predict the generated common mode before measurement.

### <In-Phase Signal>

The in-phase signal is a signal conventionally used for injection into an IC using one probe. For example, when a coaxial probe as shown in FIG. 4 is used, a signal output from coaxial core 44 is applied to an IC. The applied signal returns to coaxial outer conductor 49 through a parasitic capacitance (also called stray capacitance). Further, when the target under test or signal generation unit 10 uses the same power supply system, a signal is transmitted via a power supply line. Further, there is a signal propagation path formed with other parasitic capacitance. However, the parasitic capacitance is susceptible to arrangement of a probe and a measurement instrument, and the measurement repeatability is low. In the case of via a power supply line, since the measurement environment varies with routing of a system power supply, it is susceptible to the measurement environment and another equipment connected to the power supply line, and the measurement repeatability is less likely to be achieved.

In the present embodiment, unless there is a particular reason, it is preferable to generate only a differential signal and an in-phase signal is not generated, so that the measurement can be performed independently of the measurement environment and the arrangement of the measurement system.

The amplitude or phase may be changed using an attenuator, amplifier, or a phase shifter for one wiring. Further, in such a case as three-phase alternating current, the malfunction immunity against noise can be measured by applying a first AC signal and a second AC signal with a phase difference of 120 degrees to first probe 40 and second probe 41, respectively.

### <Control Device>

The IC noise immunity detection device may include a movable unit and a control unit for controlling scanning of first probe 40 and second probe 41.

Thus, the distance from the target under test to first probe 40 and second probe 41 can be kept constant. Keeping the distance constant can prevent change of noise that can be mixed into IC 51 under test from first probe 40 and second probe 41.

The movable unit moves first probe 40 and second probe 41 in X (lateral), Y (longitudinal), Z (height), and θ (directivity) directions of printed circuit board 50. The control unit controls scanning of the movable unit in the XYZθ directions. The movable unit and the control unit constitute scanning means for moving the position of the measured terminal of IC 51 on printed circuit board 50. The scanning means may be a robot controllable by a servo motor or the like. In addition, this control unit may control the frequency of an AC signal output by signal generator 11 or may perform a malfunction checking process. The control unit may restart equipment that does not automatically recover upon occurrence of a malfunction.

### First Modification of Sixth Embodiment

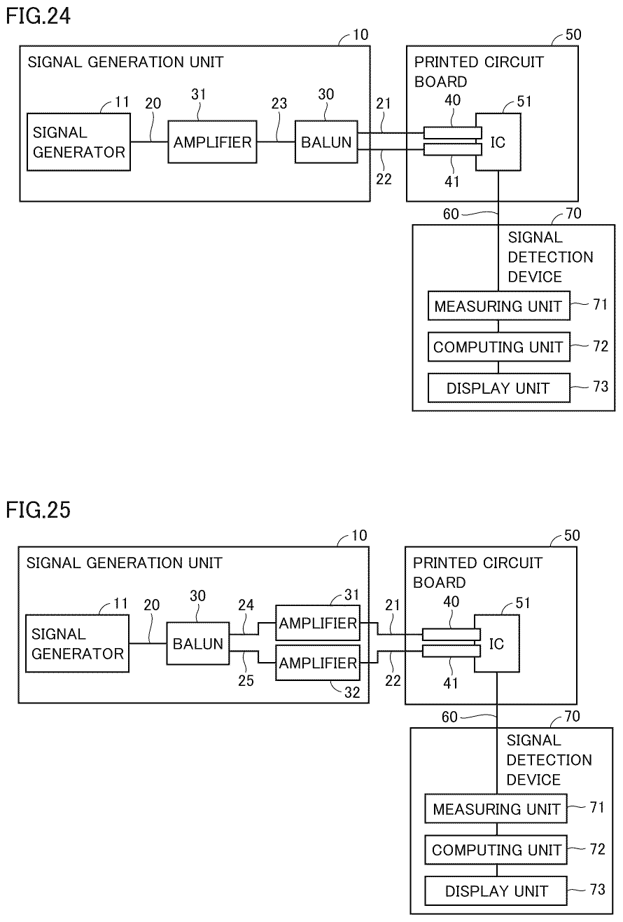

FIG. 24 is a diagram illustrating a configuration of an IC noise immunity detection device in a first modification of the sixth embodiment. Signal generation unit 10 of this IC noise immunity detection device includes an amplifier 31 arranged between signal generator 11 and balun 30. Amplifier 31 and balun 30 are connected by a coaxial cable 23.

Amplifier 31 amplifies a test signal generated by signal generator 11.

It is preferable to use amplifier 31 when the level of a test signal as electromagnetic noise injected into IC 51 is weak and changing the output voltage and frequency of signal generator 11 does not cause IC 51 to malfunction.

When the gain of amplifier 31 is fixed, an attenuator may be arranged between signal generator 11 and amplifier 31. The output power of amplifier 31 has an upper limit and the output may be distorted near the upper limit. Thus, it is preferable to separately measure the output waveform of amplifier 31 with a measurement instrument such as an oscilloscope, a spectrum analyzer, or a vector network analyzer (VNA). When the output voltage of amplifier 31 is large or when the output current of amplifier 31 is large, a coaxial cable for large voltage may be used as coaxial cable 23 between amplifier 31 and balun 30.

### Second Modification of Sixth Embodiment

FIG. 25 is a diagram illustrating a configuration of an IC noise immunity detection device in a second modification of the sixth embodiment. Signal generation unit 10 of this IC noise immunity detection device includes a first amplifier 31, a second amplifier 32, a coaxial cable 24, and a coaxial cable 25.

First amplifier 31 is arranged between balun 30 and one end of first coaxial cable 21. First amplifier 31 amplifies a first AC signal output from balun 30. Second amplifier 32 is arranged between balun 30 and one end of second coaxial cable 22. Second amplifier 32 amplifies a second AC signal output from balun 30.

Balun 30 and first amplifier 31 are connected by coaxial cable 24. Balun 30 and second amplifier 32 are connected by coaxial cable 25.

Since first amplifier 31 and second amplifier 32 each amplify a signal with a power halved by balun 30, the allowable value of output power of first amplifier 31 and second amplifier 32, and the withstand voltage and current allowable amount of balun 30 are not strict. However, since it is necessary to adjust the difference between the phase of an output signal of first amplifier 31 and the phase of an output signal of second amplifier 32, calibration of first amplifier 31 and second amplifier 32 is necessary.

### Third Modification of Sixth Embodiment

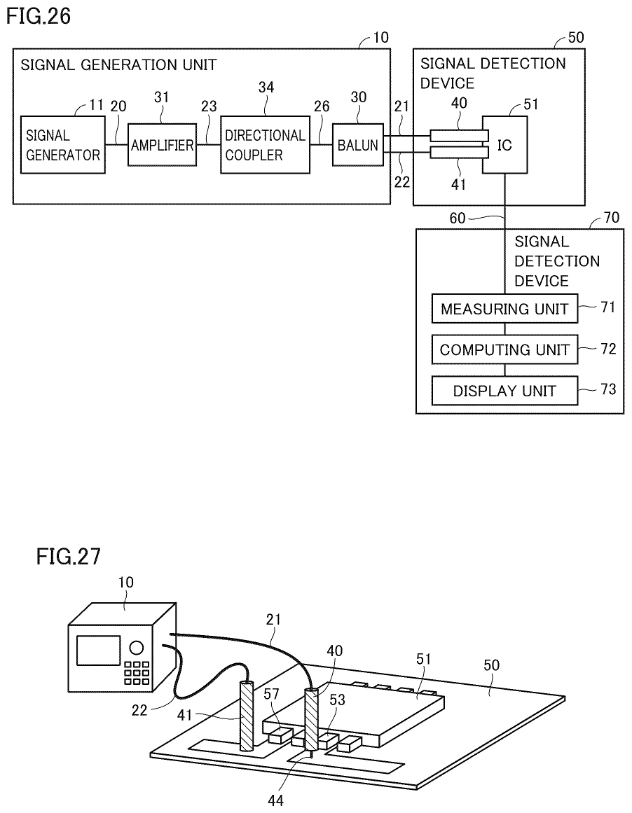

FIG. 26 is a diagram illustrating a configuration of an IC noise immunity detection device in a third modification of the sixth embodiment. Signal generation unit 10 of this IC noise immunity detection device includes a directional coupler 34 arranged between amplifier 31 and balun 30. Directional coupler 34 and balun 30 are connected by a coaxial cable 26.

Using directional coupler 34 can suppress noise flowing into amplifier 31 and signal generator 11. With the provision of directional coupler 34, the measurement instrument side appears to be a high impedance for printed circuit board 50 serving as a target under test and IC 51 on printed circuit board 50. As a result, IC noise immunity can be measured without affecting the measurement system. The provision of directional coupler 34 can prevent distortion of output of amplifier 31 and breakage of amplifier 31 even when a strong signal is input to amplifier 31. Instead of arranging directional coupler 34 between amplifier 31 and balun 30, directional couplers 34 may be arranged between balun 30 and first probe 40 and between balun 30 and second probe 41 to achieve a similar effect.

When a reflected wave of a signal propagating on a transmission line is large, that is, VSWR of load is high or return loss is small, a synthetic wave of a traveling wave and a reflective wave is measured. In such a case, directional coupler 34 can be used to extract a signal corresponding only to traveling wave power or separately extract respective signals corresponding to traveling wave power and reflected wave power. Thus, even when there is a reflected wave, power can be measured reliably.

### Seventh Embodiment

FIG. 27 is a diagram illustrating a part of an IC noise immunity detection device in a seventh embodiment.

The IC noise immunity detection device in the seventh embodiment differs from the IC noise immunity detection device in the foregoing embodiments in that first probe 40 is a contact probe.

Second probe 41 is arranged at IC 51 in a non-contact manner, as in the first embodiment.

First probe 40 is a coaxial probe. Coaxial core 44 of first probe 40 is arranged in contact with a ground terminal 53 of IC 51.

Conventionally, since the outer conductor of a probe or a reference potential is connected to the ground terminal of IC 51, a signal propagates via the ground with a low impedance.

In the present embodiment, since coaxial core 44 of first probe 40 is in contact with ground terminal 53, ground terminal 53 is insulated from the outer conductor with a low impedance. As a result, propagation of a signal via the ground with a low impedance can be prevented. Further, because of the internal resistance of balun 30 and signal generator 11, a signal is less likely to flow via core 44. Thus, even when coaxial core 44 of the first probe is brought into contact with the ground terminal of IC 51, the effect on operation of the target under test can be reduced.

First probe 40 is brought into contact with ground terminal 53 to inject noise into IC 51 more efficiently, compared with when first probe 40 is arranged at IC 51 in a non-contact manner. Furthermore, noise can be injected into feedback wiring formed such that one of two wirings transmitting differential signals is connected to the ground terminal of IC 51 and the other of two wirings transmitting differential signals is not connected to IC 51.

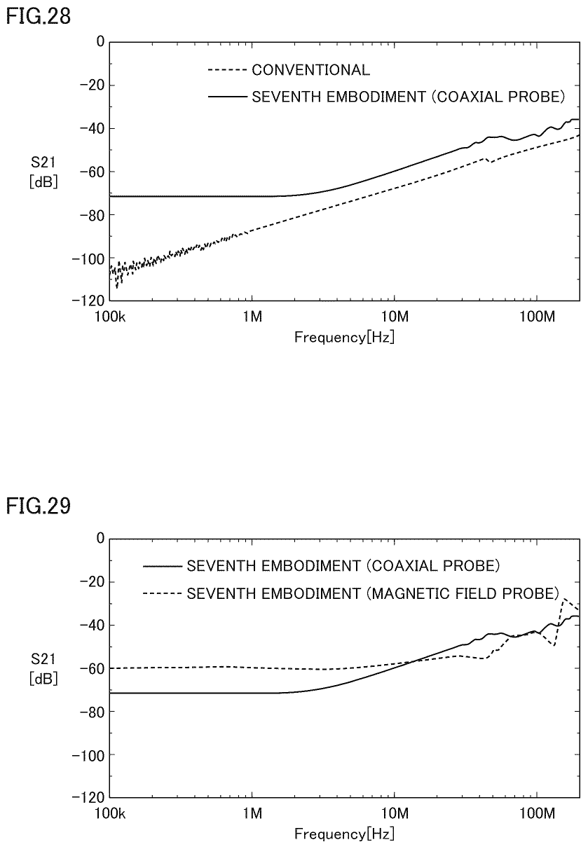

FIG. 28 is a diagram illustrating a measurement result obtained when noise is applied to printed circuit board 50. Printed circuit board 50 is a flame retardant type 4 (FR-4) substrate. The characteristic impedance of printed circuit board 50 is 50Ω, and the dielectric is 0.8 mm.

The conventional result shows the amount of coupling between a coaxial probe and a microstrip line when the core of the coaxial probe is arranged in a non-contact manner at a distance of 60 μm from the microstrip line. The result of the seventh embodiment shows the amount of coupling of a microstrip line for a differential signal input when a contact probe is connected to the GND surface of the microstrip line and the core of a coaxial probe is arranged in a non-contact manner at a distance of 60 μm from the microstrip line. As shown in FIG. 27, in the seventh embodiment, the noise injection amount increases approximately 10 dB to 40 dB in 100 kHz to 3 MHz. In the seventh embodiment, the noise injection amount increases approximately 5 dB to 10 dB in 3 MHz to 200 MHz.

FIG. 29 is a diagram illustrating a measurement result obtained when a non-contact coaxial probe (electric field probe) is used and a measurement result obtained when a magnetic field probe is used. The diameter of the magnetic field probe is 10 mm. The orientation of the magnetic field probe was set in the orientation in which the magnetic flux of the magnetic field probe was excited most to the microstrip line. As shown in FIG. 28, in up to 10 MHz, the amount of coupling between the differential signal and the microstrip line is approximately −60 dB when a magnetic field probe is used. When a magnetic field probe is used, the amount of coupling can be increased approximately 10 dB, compared with when a coaxial probe is used.

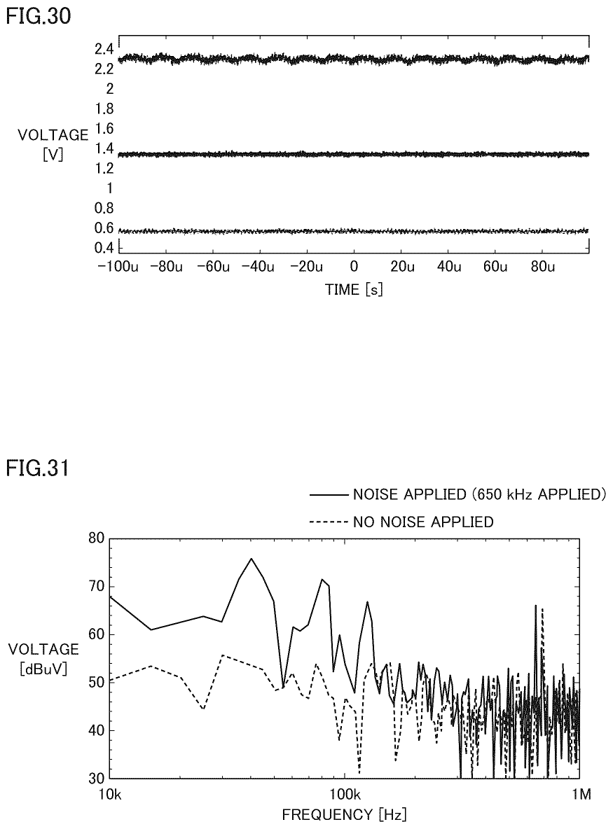

FIG. 30 is a diagram illustrating a measurement result of a normal output (1.35 V) and an abnormal output of IC 51 obtained when noise is applied to power supply IC 51. The drive frequency of power supply IC 51 is 650 kHz. According to the method in the seventh embodiment, a signal of 10 V was injected at 650 kHz into an enable signal of power supply IC 51. As shown by the waveforms in FIG. 30, the output of IC 51 changes to 2.25 V or 0.6 V at a time of abnormality.

FIG. 31 is a diagram showing the result obtained when a signal of 10 V is injected into a feedback terminal of a power supply IC. The drive frequency of the power supply IC is 650 kHz. According to the method in the present embodiment, a signal of 10 V was injected at 650 Hz into a feedback terminal of the power supply IC.

As shown in FIG. 31, a signal having a frequency different from that of the injected signal occurs. In particular, in 10 kHz to 100 kHz, noise increases approximately 20 dB. In this way, unintended noise may occur in a state immediately before a malfunction. Such noise may cause an IC supplying power to malfunction. Such a problem can be diminished by using the present embodiment.

### Modification of Seventh Embodiment

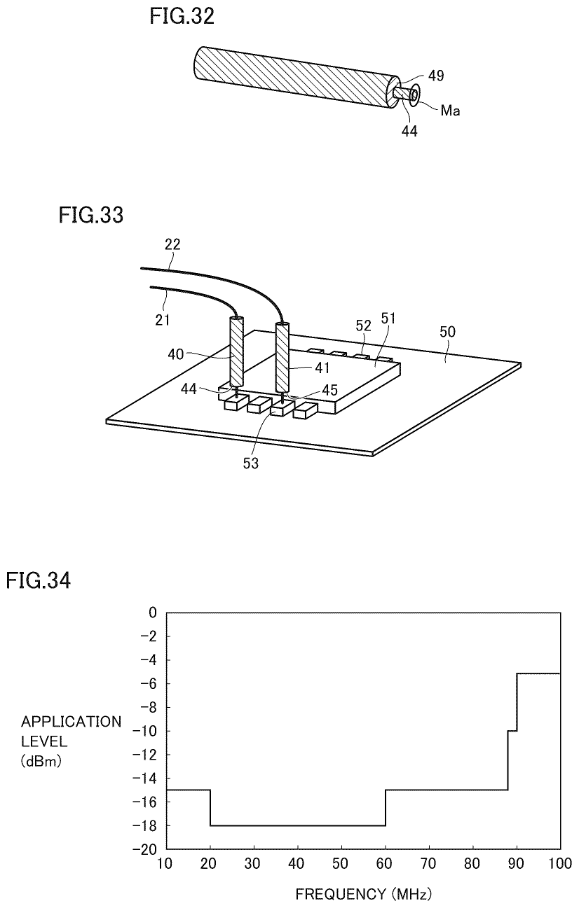

FIG. 32 is a diagram illustrating first probe 40 in a first modification of the seventh embodiment.

First probe 40 which is a coaxial probe in contact with the ground terminal of IC 51 includes a matching circuit Ma such as a capacitor attached to the tip end of coaxial core 44. The capacitor is preferably a multilayer ceramic capacitor.

Matching circuit Ma provides impedance matching between first probe 40 and signal generator 11. This can prevent occurrence of a reflected wave even when signal generator 11 such as a function generator available only for 50Ω systems is used.

Further, in a case of a target under test in which the amplitude of an output signal is large, a DC component and a low-frequency component of the target under test are less likely to be mixed into first probe 40, thereby preventing signal generator 11 from malfunctioning or being destroyed due to overvoltage.

Not only the method of arranging matching circuit Ma in series between the tip end of coaxial core 44 of first probe 40 and the target under test but also the method of arranging matching circuit Ma in parallel between the tip end of coaxial core 44 of first probe 40 and outer conductor 49 may be used.

It is preferable that signal generator 11 uses a bipolar power supply capable of outputting a signal of 1 MHz or more, irrespective of the impedance on the first probe 40 side. However, since the frequency of output of a bipolar power supply has an upper limit of approximately a few 50 MHz, the above function generator, a power amplifier, or the like can be used in the higher frequencies.

### Eighth Embodiment

FIG. 33 is a diagram illustrating a partial configuration of an IC noise immunity detection device in an eighth embodiment.

The IC noise immunity detection device in the eighth embodiment differs from the IC noise immunity detection device in the foregoing embodiments in that first probe 40 and second probe 41 are contact probes.

First probe 40 and second probe 41 are each a coaxial probe. Coaxial core 44 of first probe 40 is arranged in contact with a first terminal of IC 51. Coaxial core 45 of second probe 41 is arranged in contact with a second terminal of IC 51.

In the eighth embodiment, since a reference potential of signal generation unit 10 and a reference potential of printed circuit board 50 or IC 51 as a target under test are not directly connected, a malfunction of the target under test can be reduced by bringing first probe 40 and second probe 41 into contact.

The noise immunity detection device in the eighth embodiment is particularly effective when a differential signal is measured. In other words, a malfunction of IC 51 can be determined by bringing coaxial core 44 of first probe 40 and coaxial core 45 of second probe 41 into contact with wiring for transmitting a differential signal to inject a differential signal into IC 51. The differential signal is characterized by being less susceptible to a contact probe. It is preferable that two contact probes (first probe 40 and second probe 41) have equal shapes and that the electrical lengths from signal generation unit 10 to the contact probes are equal.

FIG. 34 is a diagram showing the malfunction condition measurement result obtained when noise is applied to differential wiring. The differential wiring used is differential wiring of a PHY chip connected to an Ethernet (registered trademark) cable. FIG. 34 indicates that even a small application level causes a malfunction in a certain frequency band (20 MHz to 60 MHz).

Coaxial core 44 of first probe 40 may be arranged in contact with wiring on printed circuit board 50 with IC 51, rather than being arranged in contact with a first terminal of IC 51. Coaxial core 45 of second probe 41 may be arranged in contact with wiring on printed circuit board 50 with IC 51, rather than being arranged in contact with a second terminal of IC 51.

### Modification of Eighth Embodiment

First probe 40 includes matching circuit Ma such as a capacitor attached to the tip end of coaxial core 44, in the same manner as in the modification of the seventh embodiment. Second probe 41 may include matching circuit Ma such as a capacitor attached to the tip end of coaxial core 44.

### Ninth Embodiment

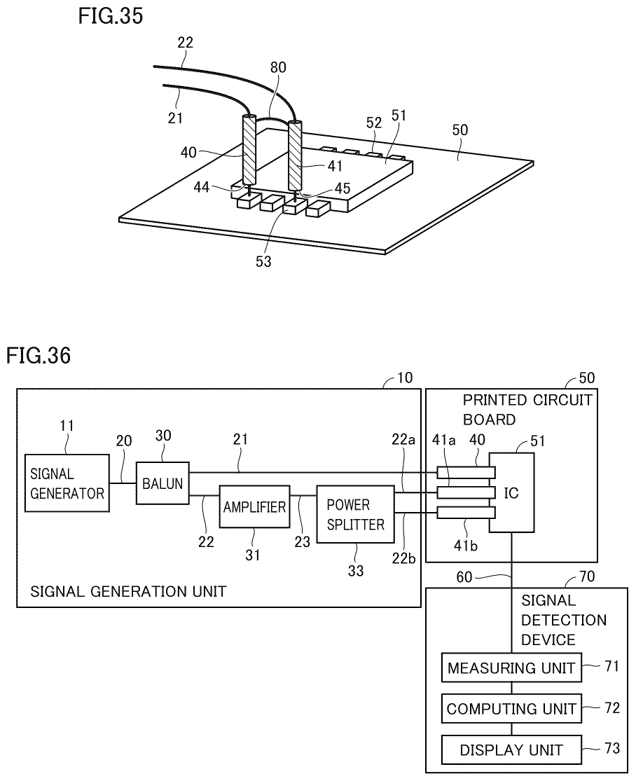

FIG. 35 is a diagram illustrating a partial configuration of an IC noise immunity detection device in a ninth embodiment.

The IC noise immunity detection device in the ninth embodiment differs from the IC noise immunity detection device in the foregoing embodiments as follows.

In the ninth embodiment, first probe 40 and second probe 41 are each a coaxial probe. The IC noise immunity detection device in the ninth embodiment includes a connecting cable 80 that connects a coaxial outer conductor of first probe 40 and a coaxial outer conductor of second probe 41.

When first coaxial cable 21 and second coaxial cable 22 are long relative to the wavelengths of the first AC signal and the second AC signal, the impedance at the tip ends of first coaxial cable 21 and second coaxial cable 22 changes to cause a standing wave in the outer conductors. As a result, measurement may be unable to be performed accurately in some frequencies. As used herein “first coaxial cable 21 and second coaxial cable 22 are long relative to the wavelengths of the first AC signal and the second AC signal” means that they are longer by approximately 1/10 wavelength or more. When the frequency of the first AC signal and the second AC signal is 300 MHz, the wavelength is 1 m. The wavelength is approximately 0.5 m due to wavelength reduction by dielectric of printed circuit board 50, and then the 1/10 wavelength is approximately 5 cm.

When coaxial cables 21, 22 are short relative to the wavelength, the outer conductors have equal potential through signal generator 11 and balun 30, and a standing wave does not occur in the outer conductors. When coaxial cables 21, 22 are longer than the wavelength by 1/10 wavelength or more, the effect of standing wave increases. In such a case, connecting cable 80 for connecting the outer conductors close to first probe 40 and second probe 41 can be provided to reduce the effect of coaxial cables 21, 22. Since the residual inductance of connecting cable 80 itself has an effect in some frequencies, it is preferable that connecting cable 80 is thick and short. Further, the outer conductors may be soldered to each other, rather than point connection as in connecting cable 80, so that measurement to higher frequencies is possible without producing a standing wave.

### Tenth Embodiment

FIG. 36 is a diagram illustrating a configuration of an IC noise immunity detection device in a tenth embodiment.

The IC noise immunity detection device includes signal generation unit 10, first probe 40, second probes 41a, 41b, determination device 70, first coaxial cable 21, and second coaxial cables 22a, 22b.

Signal generation unit 10 outputs a first AC signal and a second AC signal having different phases as noise. The first AC signal and the second AC signal can be differential signals.

First coaxial cable 21 transmits a first AC signal.

Second coaxial cables 22a, 22b transmit a second AC signal.

First probe 40 is connected to first coaxial cable 21. First probe 40 is arranged in proximity to IC 51 on printed circuit board 50 and injects the first AC signal into IC 51. First probe 40 may be arranged at IC 51 on printed circuit board 50 in a non-contact manner.

Second probe 41a is connected to second coaxial cable 22a. Second probe 41a is arranged in proximity to the IC on printed circuit board 50 and injects the second AC signal into IC 51. Second probe 41b is connected to second coaxial cable 22b. Second probe 41b is arranged in proximity to the IC on printed circuit board 50 and injects the second AC signal into IC 51. Second probes 41a, 41b may be arranged at IC 51 on printed circuit board 50 in a non-contact manner.

Determination device 70 determines whether IC 51 is malfunctioning, based on a state of IC 51 after injection of the first AC signal and the second AC signal. For example, determination device 70 may determine whether IC 51 is malfunctioning, based on an output signal from IC 501.

Signal generation unit 10 includes signal generator 11, balun 30, amplifier 31, and a power splitter 33. Since the characteristic impedance of the probe is not always 50Ω, power splitter 33 may be any distributor that distributes a high-frequency signal or power, such as a power divider or a balun. Signal generator 11 generates a test signal that is electromagnetic noise.

Balun 30 generates a first AC signal and a second AC signal with equal amplitude and a phase difference of 180 degrees, from a test signal generated by signal generator 11. The port of balun 30 that outputs the first AC signal is connected to first coaxial cable 21.

Amplifier 31 amplifies the second AC signal.

Power splitter 33 is connected to the output of amplifier 31. Power splitter 33 splits the output of amplifier 31.

Two outputs of power splitter 33 are connected to second coaxial cables 22a and 22b.

According to the present embodiment, noise can be injected simultaneously into a plurality of points in an IC. For example, noise can be injected simultaneously into signals of an operational amplifier and a power supply.

When a signal line is immune to noise and a power supply line is vulnerable to noise, an amplifier may be arranged immediately before first probe 40 or second probe 41a, 41b arranged in the vicinity of the signal line. Further, first probe 40 and second probes 41a, 41b may be contact probes. For example, when it is known that an internal circuit of IC 51 includes a comparator, a contact probe may be attached to wiring transmitting GND and a differential signal, and a non-contact probe may be attached to the power supply.

First probe 40 and second probes 41a, 41b may be current probes, Rogowski coils, or the like. All the probes are not necessarily arranged in proximity to IC 51 or printed circuit board 50. Noise may be injected into a connector connected to printed circuit board 50. For example, IC 51 may have a plurality of power supply terminals with equal potentials in order to ensure a current capacity. In such a case, second probe 41a may be arranged in proximity to one power supply terminal of IC 51, second probe 41b may be arranged in proximity to another power supply terminal of IC 51, and first probe 40 may be arranged in proximity to the ground terminal of IC 51. Thus, signals can be injected simultaneously into a plurality of power supply terminals, thereby efficiently injecting noise into IC 51.

### Eleventh Embodiment

The measurement time should be reduced because there are many measurement parameters such as frequency, amplitude, and combinations of IC terminals. Most of the measurement time is the time for scanning a probe. In the foregoing embodiments, two probes for noise application and one probe for signal detection are used, and the probes may be entangled to prevent automatic measurement.

In the present embodiment, a probe for applying noise and a probe for detecting an output signal are arranged in advance in the vicinity of an IC as a target under test, and the probe for application and the probe for detection are mechanically or electrically switched to solve the above problem.

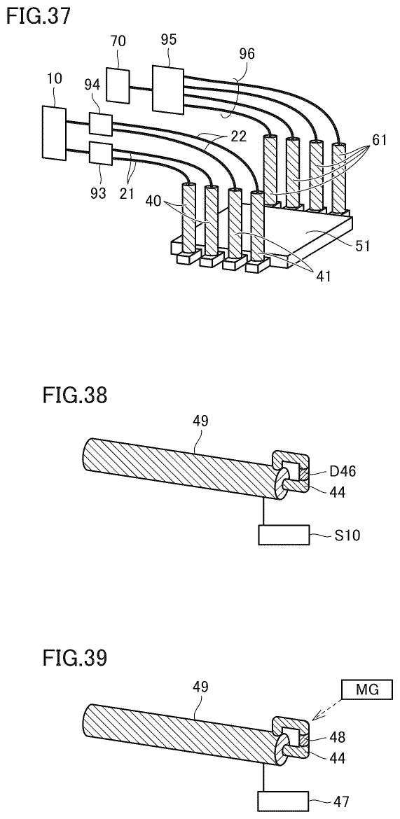

FIG. 37 is a diagram illustrating a configuration of an IC noise immunity detection device in an eleventh embodiment.

The IC noise immunity detection device includes signal generation unit 10, a plurality of first coaxial cables 21, a plurality of second coaxial cables 22, a plurality of third coaxial cables 96, a plurality of first probes 40, a plurality of second probes 41, a plurality of third probes 61, a first switch 93, a second switch 94, and a third switch 95.

Signal generation unit 10 outputs a first AC signal and a second AC signal having different phases as noise.

First coaxial cable 21 transmits a first AC signal.

Second coaxial cable 22 transmits a second AC signal.

First probe 40 is connected to the corresponding first coaxial cable 21. First probe 40 is arranged in proximity to IC 51 on printed circuit board 50 and injects the first AC signal into IC 51.

Second probe 41 is connected to the corresponding second coaxial cable 22. Second probe 41 is arranged in proximity to IC 51 on printed circuit board 50 and injects the second AC signal into IC 51.

Third probe 61 is arranged in proximity to IC 51 on printed circuit board 50 and measures an output signal of IC 51.

Third coaxial cable 96 is connected to the corresponding third probe 61 and transmits an output signal of IC 51.

Determination device 70 determines whether IC 51 is malfunctioning, based on an output signal of IC 51 input from third probe 61 after injection of the first AC signal and the second AC signal.

First switch 93 is provided between a plurality of first coaxial cables 21 and signal generation unit 10. First switch 93 switches one first coaxial cable 21 to be connected to signal generation unit 10.

Second switch 94 is provided between a plurality of second coaxial cables 22 and signal generation unit 10. Second switch 94 switches one second coaxial cable 22 to be connected to signal generation unit 10.

Third switch 95 is provided between a plurality of third coaxial cables 96 and determination device 70. Third switch 95 switches one third coaxial cable 96 to be connected to determination device 70.

First probes 40, second probes 41, and third probes 61 may be either non-contact probes or contact probes. First probes 40, second probes 41, and third probes 61 may be of the same kind or different kinds.

In the present embodiment, the switch is switched by an electrical signal to switch a probe to be used, so that detection of noise immunity of IC 51 can be carried out for a short time. It is possible to reduce the possibility that probes and coaxial cables are entangled with scanning of a probe to stop or break the robot arm, and the possibility that the probe and the target under test are short-circuited. In particular, in a case of a coaxial probe in which an electric field is concentrated on the tip end, the interference between a plurality of coaxial probes is small and accurate measurement can be performed even when a plurality of coaxial probes are densely arranged to be matched with the IC terminals. On the other hand, in a case of a loop probe in which a magnetic field appears in a direction orthogonal to the loop surface of the probe, if there is another loop probe nearby, interference occurs between the probes to make it difficult to grasp malfunction characteristics. In such a case, the interference can be reduced by increasing the distance between a plurality of probes or by arranging a plurality of probes such that the respective loop surfaces of the loop probes are orthogonal to each other. Therefore, coaxial probes are preferred to measure minute ICs for the above reasons. However, when the characteristics of a target under test are unknown, for example, to search for a terminal prone to malfunction, it is preferable to use a magnetic field probe capable of grasping a rough position.

In order to reduce the interference between probes, it is preferable to decrease the distance between the tip end of each probe and the target under test, rather than the distance between the tip ends of the probes. By doing so, parasitic capacitance and mutual inductance are likely to occur between the probe and the target under test. As a result, the amount injected into the target under test can be increased, compared with the amount of a signal returning to signal generation unit 10 or determination device 70 through another probe.

The impedance can also be measured using a device having a similar signal switch. As for switching between an electric field probe and a magnetic field probe, measurement can be performed without replacing the probes, using an external switch formed of a semiconductor element to open or short-circuit the tip ends of the probes. However, when an external switch is used, it is necessary to arrange the switch so that its signal does not affect the equipment.

For the arrangement in consideration of the directivity of the probe, it is preferable to arrange in the orientation in which the amount of coupling between the probe and the target under test is maximum, in the same manner as in the foregoing embodiments.

### Twelfth Embodiment

In the fourth embodiment, in order to perform the internal impedance measurement method for IC 51, it is necessary to arrange the electric field probe and the magnetic field probe at the same position in the target under test. However, when the electric field probe and the magnetic field probe are physically moved, the time for movement is required. Moreover, since the size of the tip end of the electric field probe and the size of the tip end of the magnetic field probe are not always the same, these probes are not always able to be arranged at the same position.

FIG. 38 is a diagram illustrating an electromagnetic field probe in a twelfth embodiment.

This electromagnetic field probe is used for measuring an electric field and a magnetic field of a terminal of IC 51. This electromagnetic field probe is a coaxial probe having outer conductor 49 and core 44.

The tip end of core 45 and outer conductor 49 are connected through a diode D46.

A switching unit SW such as a switch or a duplexer is provided to switch whether to apply a DC voltage from a DC power supply such as a battery between the tip end of core 44 and outer conductor 49 of the coaxial probe. When switching unit SW is on, the resistance of diode D46 is small and thus the electromagnetic field probe in FIG. 38 functions as a magnetic field probe. When switching unit SW is off, the resistance of diode D46 is large and thus the electromagnetic field probe in FIG. 38 functions as an electric field probe.

Whether to operate the electromagnetic field probe as an electric field probe or as a magnetic field probe can be electrically switched only by an external signal, thereby solving the problems including the time for movement and the sizes of the probes as described above. In impedance measurement, it is most preferable that an electric field and a magnetic field are measured at the same position at the same time. However, this is physically impossible. However, for example, when the signal rate is 1 MHz, on/off is switched using the above switch or diode at 100 MHz, whereby an electric field and a magnetic field can be measured before the electrical characteristics of the target under test change. However, with a single trial, the measurement timing may overlap with the timing when the on/off of the target under test is switched. Therefore, measurement is performed multiple times and the average is determined statistically or only when the same characteristics appear, whereby an electric field and a magnetic field can be measured equivalently at the same position at the same time.

This electromagnetic field probe can be used as a probe that not only detects noise but also applies noise in the same manner as in the first embodiment. In this case, it is preferable to use a duplexer such as a bias tee to superimpose a high-frequency signal on a DC signal. Further, a passive circuit such as a DC cut may be used to remove a DC component for input to the measurement instrument.

### Modification of Twelfth Embodiment

FIG. 39 is a diagram illustrating an electromagnetic field probe in a modification of the twelfth embodiment.

The electromagnetic field probe in this modification includes a reed switch 48 instead of diode D46 and a magnet MG for controlling reed switch 48.

For example, magnet MG is a permanent magnet. The open/close of reed switch 48 can be switched by bringing the permanent magnet closer to or away from reed switch 48.

Alternatively, magnet MG is an electromagnet. The electromagnet is arranged in the vicinity of reed switch 48, and the open/close of reed switch 48 can be switched by feeding current to the electromagnet. The electromagnetic field probe has been described above as a detection probe for detecting an electric field and a magnetic field. However, it may be used as a probe for noise application to a target under test as described in the first embodiment.

### Thirteenth Embodiment

The present embodiment relates to the use in actual electronic equipment. The foregoing embodiments relate to general IC evaluation methods, whereas the method in the present embodiment can be effectively used when a specific noise source is predictable. Specific examples will be given below.

Testing that replicates an actual use environment includes electrostatic testing (ESD testing) for use in the electromagnetic compatibility (EMC) field, fast transient/burst (EFT/B) testing, and lightning surge testing. Since the output waveform of such a tester serving as a noise source can be measured by an oscilloscope or the like, the frequency characteristics of the noise source can be grasped. Propagation from the noise source to a desired IC is via a conduction or spatial propagation path or both.

When the noise source is known, the frequency characteristics of noise immunity of the IC are known by the methods described in the first to twelfth embodiments. Therefore, if the propagation from the noise source to the IC can be predicted, the frequency characteristics of noise applied to the IC can be grasped.

The propagation characteristics from the noise source to a desired IC terminal, specifically, S-parameters can be calculated using an electromagnetic field simulator such as HFSS from Ansys, Inc. or CST Studio from CST.

Further, more accurate propagation characteristics can be grasped by grasping the internal impedance of each terminal of the IC, as described in the third embodiment. Then, the voltage and power applied to the IC can be estimated by combining the frequency characteristics of the noise source as an input signal and the frequency characteristics of the propagation path.

Specifically, the characteristics of propagation from a signal generating device producing noise to a terminal having a malfunction can be estimated by coupling S-parameters calculated by an electromagnetic field simulator or through actual measurement with a flow graph (or signal flow graph) of S-parameters. This method is known as a method that combines amplification and attenuation characteristics of each individual component in the form of a level diagram in design of radio sets or the like. The present method is an extended one of the level diagram in radio set design. In particular, in the present embodiment, this method is called noise level diagram, because each component (for example, a component in which a noise application device to probes are integrated, or a printed circuit board to which noise is applied) has the amplitude characteristics and the phase characteristics of frequency and is formed only with the attenuation characteristics without amplification. In the noise level diagram, unlike the radio set design, it is necessary to consider the propagation delay time for each frequency and the reflection and transmission characteristics at a coupling section of components and thus it is important to include the phase characteristics in coupling. The frequency characteristics of the noise level applied to a terminal of the IC having a malfunction can be estimated by coupling this noise level diagram with the frequency characteristics of the signal level of the signal generator. Further, the presence/absence of malfunction can be determined by comparing the frequency characteristics of the noise level applied to the terminal of the IC with the malfunction frequency characteristics of noise described in the foregoing embodiments.

EMS, that is, noise immunity can be predicted accurately in a front-loading design without a prototype of a malfunction of an IC, by comparing the result of evaluation using the voltage and power applied to the IC and the IC noise immunity evaluation device described in the first to twelfth embodiments.

Specifically, as an example that requires EMS design, the technique described in the present embodiment is used in electronic equipment accessible by persons, such as an elevator operation panel having a touch panel and buttons, an operation device for FA equipment, electronic equipment having a touch panel such as a smart phone, to achieve a design that can prevent malfunction and destruction.

In places where equipment that disturbs an electromagnetic noise environment flows in surrounding or proximate cables, such as power plants or factories, electromagnetic noise is mixed into a communication cable described in the present embodiment and mixed into a power supply cable through a system power source, due to magnetic coupling. In such a case, the method described in the present embodiment enables design that minimizes noise effects on ICs in a design stage. If necessary, a path to release noise can be provided by arranging an electromagnetic shield, a varistor, an arrestor, or a ground capacitor. In power plants or factories, momentary interruption and malfunction are fatal and the design method according to the present technique is highly effective.

Further, in space industry, military industry, automobile industry (especially automatic assistance or self-driving) involving autonomous operation, jamming and the like causes malfunction or destruction of equipment. Human judgment does not work instantaneously, possibly causing a fatal result. By applying the present technique, electronic equipment immune to jamming can be made, so that the problem described above is less likely to occur.

In addition, for example, in equipment for consumer use, such as air conditioners, destruction of equipment by induced lightning should be reduced. Most of destruction due to induced lightning is attributable to that lightning is inducted to, for example, neighboring transmission lines. Thus, a path into which noise resulting from induced lightning is mixed is produced via a power supply line. Ideally, current is fed to the ground by a ground capacitor or the like before noise is mixed into equipment. However, it is impossible to feed all to the ground since lightning is also an AC signal and affected by residual inductance. Therefore, some is mixed into the inside of the equipment. The present technique can predict such a path before making a prototype.

It is a good method to evaluate noise immunity by the present technique and improve immunity against disturbance noise to a semiconductor element itself. In particular, the response map and the like are written in a specification sheet or the like and shared with printed circuit board designers to enable development with fewer troubles.

The printed circuit board designers, receiving the result of evaluation by the present technique, can avoid selecting an IC susceptible to noise. Further, it is a desirable design method to append the degree of effect of disturbance noise for each IC terminal in a circuit diagram. In particular, possible EMS troubles that may occur after design can be minimized by describing the bands with low noise immunity and requiring caution against noise, and providing a description to pay attention to adding noise filter components and routing of wiring.

### Fourteenth Embodiment

A specific calculation method of estimating impedance using the measurement result of an electric field and a magnetic field in a non-contact manner described in the third embodiment, and the result of calculation of the measurement result using the method will be described. The measurement was performed in a condition in which the impedance is known to show the evaluation result. Specifically, a signal generator (specifically, a vector network analyzer) was connected to one end of a microstrip line with a characteristic impedance of 50Ω using a FR-4 substrate with a dielectric thickness of 0.8 mm. An electric field and a magnetic field were measured when the termination was open and when it was short-circuited. Specifically, an electric field and a magnetic field were measured with different ports of the vector network analyzer.

For impedance estimation, a method of simply determining a ratio between electric field and magnetic field may be contemplated. However, it was found that the estimation accuracy is low with this method. Then, in the present embodiment, the ratio between electric field and magnetic field is calibrated by a correction coefficient calculated using a known impedance Z0. Specifically, the following equation holds, where the frequency characteristics of received voltage of the electric field probe is V1(f) and the frequency characteristics of received voltage of the magnetic field probe is V2(f).

$$V 1 ( f ) = α 1 ( f ) \times E ( f ) \qquad ( 2 )$$

$$V 2 ( f ) = α 2 ( f ) \times E ( f ) \qquad ( 3 )$$

The impedance Z(f) to be estimated is represented by the following equation. α1(f), α2(f), and β(f) are complex coefficients dependent on the frequency. α1(f) and α2(f) are known complex coefficients. β(f) is an unknown complex correction coefficient.

$$\begin{matrix}[ Number 1 ] & \\ Z ( f ) = \frac{E ( f )}{H ( f )} = \frac{{α}_{1} ( f ) {V}_{1} ( f )}{{α}_{2} ( f ) {V}_{2} ( f )} = β ( f ) \frac{{V}_{1} ( f )}{{V}_{2} ( f )} & ( 4 )\end{matrix}$$

The unknown complex correction coefficient β(f) can be calculated by the known impedance element Z0 [Ω]. Specifically, β(f) is calculated by the following equation. When electric field E(f) and magnetic field H(f) are measured in order to find the complex correction coefficient β(f), it is preferable to fix the positional relation between the electric field probe and the target under test and the positional relation between the magnetic field probe and the target under test.

$$\begin{matrix}[ Number 2 ] & \\ β ( f ) = 20 {log}_{10} ( {Z}_{0} \times 1 {0}^{{V}_{2} ( f )} ) - {V}_{1} ( f ) & ( 5 )\end{matrix}$$

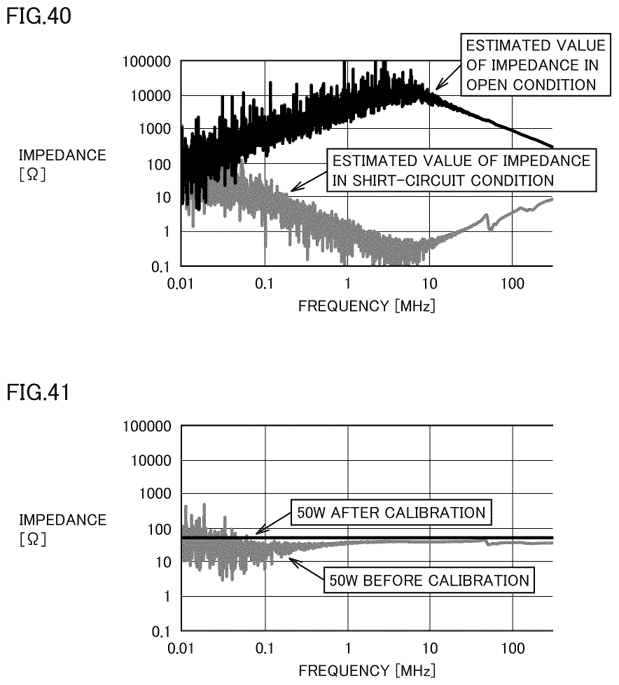

FIG. 40 is a diagram illustrating an estimation result of internal impedance Z(f) in a fourteenth embodiment.

FIG. 40 illustrates the result of calculating internal impedance Z(f) using the complex correction coefficient β(f) calculated using an input terminal with known impedance Z0=50Ω. In 100 kHz to 100 MHz, the internal impedance Z(f) in a short-circuit condition is approximately 1Ω and the internal impedance Z(f) in an open condition is approximately 1 kΩ.

FIG. 41 is a diagram showing the frequency characteristics of an estimation value of internal impedance Z(f) for a 50Ω terminator when calibration by a correction complex coefficient β(f) according to the fourteenth embodiment is performed and when calibration is not performed.

When calibration is performed, internal impedance Z(f) is a constant value (50Ω). When calibration is not performed, that is, when internal impedance Z(f) is calculated simply using the ratio between electric field and magnetic field, internal impedance Z(f) is not a constant value (50Ω). In the present case, 50Ω was used as the known impedance Z0. However, the estimation accuracy of internal impedance Z(f) of the input terminal under test can be improved using the known impedance Z0 presumably close to impedance Z(f) of the input terminal under test.

The calibration according to the present embodiment is advantageous in that a phase component can be used. Since the phase component in a frequency band indicates a time difference in a time domain, temporal change of impedance can be measured, which is not possible with conventional techniques that do not use calibration by including a phase component. Thus, the internal impedance in on and off of a power semiconductor element, which is a kind of ICs, and in a transient state can be estimated in a non-contact manner. As a result, accurate design is possible in a circuit simulation in a design early stage.

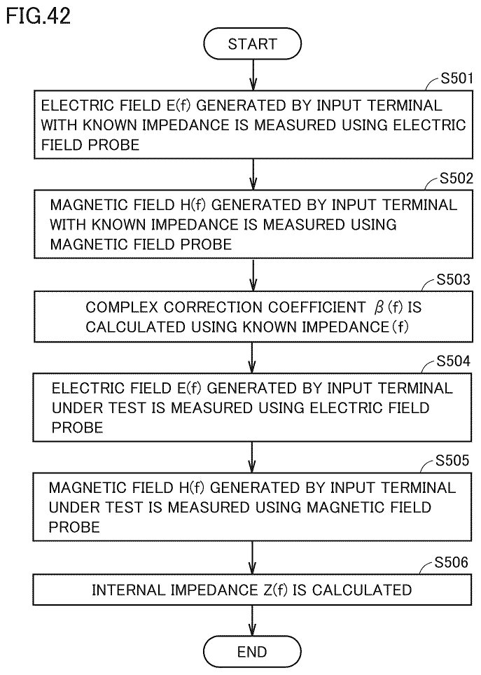

FIG. 42 is a flowchart illustrating the procedure of a method of measuring an internal impedance in the fourteenth embodiment.

At step S501, an electric field probe is arranged in the vicinity of an input terminal PI(0) with known impedance Z0 of IC 51 in an operative state, and electric field E(f) generated by input terminal PI with known impedance Z0 is measured using the electric field probe in a non-contact manner.

At step S502, a magnetic field probe is arranged at the same place as the place where the electric field probe is arranged, and a magnetic field H(f) generated by input terminal PI(0) with known impedance Z0 is measured by the magnetic field probe in a non-contact manner.

At step S503, determination device 70 calculates voltage V1(f) according to equation (2) from the electric field E(f) measured at step S501. Determination device 70 calculates voltage V2(f) according to equation (3) from the magnetic field H(f) measured at step S502. Determination device 70 calculates complex correction coefficient β(f) according to equation (5) from the calculated V1(f) and V2(f) and the known impedance Z0.

At step S504, an electric field probe is arranged in the vicinity of input terminal PI under test of IC 51 in the operative state, and electric field E(f) generated by input terminal PI under test is measured by the electric field probe in a non-contact manner.

At step S505, a magnetic field probe is arranged at the same place as the place where the electric field probe is arranged, and a magnetic field H(f) generated by input terminal PI under test is measured by the magnetic field probe in a non-contact manner.

At step S503, determination device 70 calculates voltage V1(f) according to equation (2) from the electric field E(f) measured at step S504. Determination device 70 calculates voltage V2(f) according to equation (3) from the magnetic field H(f) measured at step S505. Determination device 70 calculates the internal impedance of input terminal PI under test according to equation (4), using the calculated V1(f) and V2(f), and complex correction coefficient β(f) measured at step S503.

Embodiments disclosed here should be understood as being illustrative rather than being limitative in all respects. The scope of the present disclosure is shown not in the foregoing description but in the claims, and it is intended that all modifications that come within the meaning and range of equivalence to the claims are embraced here.

### REFERENCE SIGNS LIST

10 signal generation unit, 11 signal generator, 20, 21, 22, 22a, 22b, 23, 24, 25, 26, 96 coaxial cable, 30 balun, 31, 32 amplifier, 33 power splitter, 34 directional coupler, 40, 41, 41a, 41b, 61 probe, 44, 45 core, 48 reed switch, 49 outer conductor, 50 printed circuit board, 51 IC, 53 ground terminal, 54 first noise applied section, 55 second noise applied section, 60 measurement cable, 70 determination device, 71 measuring unit, 72 computing unit, 73 display unit, 80 connecting cable, 91 temperature detector, 92 antenna, 93 first switch, 94 second switch, 95 third switch, C42, C43 capacitor, D46 diode, Ma matching circuit, P1, P2 output port, SW switching unit.

1. An IC noise immunity detection device comprising:
a signal generation unit to output a first AC signal and a second AC signal with different phases as noise;
a first coaxial cable to transmit the first AC signal;
a second coaxial cable to transmit the second AC signal;
a first probe connected to an end opposite to the signal generation unit in the first coaxial cable and arranged in proximity to an IC on a printed circuit board;
a second probe connected to an end opposite to the signal generation unit in the second coaxial cable and arranged in proximity to the IC; and
a determination device to determine whether the IC is malfunctioning, based on an operating state of the IC or a device having the IC after the first AC signal and the second AC signal are applied.

2. The IC noise immunity detection device according to claim 1, wherein a phase difference between the first AC signal and the second AC signal is 180 degrees.

3. The IC noise immunity detection device according to claim 1, wherein a phase difference between the first AC signal and the second AC signal is 120 degrees.

4. The IC noise immunity detection device according to claim 1, wherein the determination device determines whether the IC is malfunctioning, based on an output signal of the IC or an IC different from the IC that is connected to the IC.

5. The IC noise immunity detection device according to claim 1, further comprising a temperature detector to detect a temperature of the IC,
wherein the determination device determines whether the IC is malfunctioning, based on a temperature change of the IC or an IC different from the IC that is connected to the IC.

6. The IC noise immunity detection device according to claim 1, further comprising an antenna to detect an electromagnetic wave emitted from the IC,
wherein the determination device determines whether the IC is malfunctioning, based on change in received voltage at the antenna in a frequency band other than a frequency band of the first AC signal and the second AC signal.

7. The IC noise immunity detection device according to claim 1, wherein the signal generation unit includes
a signal generator to generate a test signal and
a signal distributor to generate, from the test signal, the first AC signal and the second AC signal with equal amplitudes and a phase difference of 180 degrees.

8.-10. (canceled)

11. The IC noise immunity detection device according to claim 1, wherein
a terminal to which the first AC signal and the second AC signal are applied is a signal input terminal or a signal input/output terminal of the IC, and
a terminal at which an output signal from the IC is observed is a signal output terminal or a signal input/output terminal of the IC.

12. The IC noise immunity detection device according to claim 1, wherein the first probe and the second probe are arranged at the IC in a non-contact manner.

13. The IC noise immunity detection device according to claim 1, wherein
the first probe is a coaxial probe,
a coaxial core of the coaxial probe is arranged in contact with a ground terminal of the IC, and
the second probe is arranged at the IC in a non-contact manner.

14. The IC noise immunity detection device according to claim 2, wherein
the first probe and the second probe are each a coaxial probe,
a coaxial core of the first probe is arranged in contact with a first terminal of the IC, and
a coaxial core of the second probe is arranged in contact with a second terminal of the IC.

15. The IC noise immunity detection device according to claim 13, further comprising a matching circuit attached to a tip end of the coaxial probe.

16. The IC noise immunity detection device according to claim 1, wherein
the first probe and the second probe are each a coaxial probe, and
the IC noise immunity detection device further comprises a cable to connect a coaxial outer conductor of the first probe and a coaxial outer conductor of the second probe.

17. The IC noise immunity detection device according to claim 1, wherein the signal generation unit includes
a signal generator to generate a test signal,
a first signal distributor to output the first AC signal and the second AC signal with equal amplitudes and a phase difference of 180 degrees, from the test signal,
an amplifier to amplify the second AC signal, and
a second signal distributor connected to an output of the amplifier,
the IC noise immunity detection device comprises:
two second coaxial cables connected to an output of the second signal distributor; and
two second probes each connected to a corresponding second coaxial cable.

18. The IC noise immunity detection device according to claim 1, further comprising an electromagnetic field probe to measure an electric field and a magnetic field of a terminal of the IC, wherein
the electromagnetic field probe is a coaxial probe having an outer conductor and a core,
a tip end of the core and the outer conductor are connected through a diode, and
the IC noise immunity detection device further comprises a switching unit to control on/off of DC voltage application between the tip end of the core and the outer conductor.

19. The IC noise immunity detection device according to claim 1, further comprising an electromagnetic field probe to measure an electric field and a magnetic field of a terminal of the IC, wherein
the electromagnetic field probe is a coaxial probe having an outer conductor and a core,
a tip end of the core and the outer conductor are connected through a reed switch, and
the IC noise immunity detection device further comprises a magnet to control the reed switch.

20. An IC noise immunity detection device comprising:
a signal generation unit to output a first AC signal and a second AC signal with different phases;
a plurality of first coaxial cables, each transmitting the first AC signal;
a plurality of second coaxial cables, each transmitting the second AC signal;
a plurality of first probes each connected to a corresponding first coaxial cable and arranged in proximity to an IC on a printed circuit board to apply the first AC signal to the IC;
a plurality of second probes each connected to a corresponding second coaxial cable and arranged in proximity to the IC to apply the second AC signal to the IC;
a plurality of third probes each arranged in proximity to the IC to measure an output signal of the IC;
a plurality of third coaxial cables each connected to a corresponding third probe to transmit an output signal of the IC;
a determination device to determine whether the IC is malfunctioning, based on an output signal of the IC input from the third probe, after application of the first AC signal and the second AC signal;
a first switch provided between the first coaxial cables and the signal generation unit to switch one of the first coaxial cables to be connected to the signal generation unit;
a second switch provided between the second coaxial cables and the signal generation unit to switch one of the second coaxial cables to be connected to the signal generation unit; and
a third switch provided between the third coaxial cables and the determination device to switch one of the third coaxial cables to be connected to the determination device.

21. An IC noise immunity detection method in an IC noise immunity detection device comprising a signal generation unit to output a first AC signal and a second AC signal with different phases, a first coaxial cable to transmit the first AC signal, a second coaxial cable to transmit the second AC signal, a first probe connected to the first coaxial cable, a second probe connected to the second coaxial cable, and a determination device, the IC noise immunity detection method comprising the steps of:
arranging the first probe and the second probe in proximity to the IC;
outputting, by the signal generation unit, the first AC signal and the second AC signal; and
determining, by the determination device, whether the IC is malfunctioning, based on a state of the IC, or a printed circuit board having the IC, or a different printed circuit board connected to the printed circuit board having the IC.

22. (canceled)

23. The IC noise immunity detection method according to claim 21, further comprising the steps of:
changing frequency and amplitude of the first AC signal and the second AC signal output from the signal generation unit; and
creating a response map indicating an output signal of the IC in a combination of frequency of the first AC signal and the second AC signal and amplitude of the first AC signal and the second AC signal.

24. The IC noise immunity detection method according to claim 23, further comprising a step of changing a terminal of the IC to which the first AC signal and the second AC signal are applied, wherein
the step of creating a response map includes a step of creating a response map indicating an output signal of the IC in a combination of a terminal or between terminals of the IC, frequency of the first AC signal and the second AC signal, and amplitude of the first AC signal and the second AC signal.

25.-29. (canceled)
